(19) United States
(12) Patent Application Publication
(10) Pub. No.: US 2009/0140276 A1
(43) Pub. Date: Jun. 4, 2009

(54) OPTICAL FUNCTIONAL FILM AND METHOD OF MANUFACTURING THE SAME

(75) Inventor: Tomoaki Kuratate, Nara (JP)

Correspondence Address: SHARP KABUSHIKI KAISHA;C/O KEATING & BENNETT, LLP, 1800 Alexander Bell Drive, SUITE 200, Reston, VA, 20191, US

(73) Assignee: SHARP KABUSHIKI KAISHA, Osaka-shi (JP)

(21) Appl. No.: 11/815,152

(22) PCT Filed: Jan. 24, 2006
(86) PCT No.: PCT/JP2006/301030

§ 371 Date: Jul. 31, 2007

(30) Foreign Application Priority Data
Jan. 31, 2005 (JP) 2005-023236

(51) Int. Cl. H01L 27/00; H01L 21/00

(52) U.S. Cl. 257/98; 438/29; 257/E21.001; 257/E27.001

(57) ABSTRACT

A light emitting element includes a light emitting layer emitting light and a refractive index composite structure layer arranged in a light path of the light output from the light emitting layer. The refractive index composite structure layer includes a structure having characteristics (1) to (4) as follows: (1) an internal configuration includes two or more types of phases differing in refractive index; (2) at least one of the two or more types of phases includes a structural unit having a size greater than or equal to 1 nm and smaller than or equal to ¼ of a wavelength within a visible light wavelength range; (3) an average refractive index is higher than 1 and lower than a refractive index of a plurality of layers between a light emitter and the refractive index composite structure layer excepting a layer including a gas phase; and (4) the internal configuration in a thickness direction includes a plurality of interfaces between the two or more types of phases in a near-field region into which light as energy can enter from an interface between the optical functional film and another layer adjacent to the refractive index composite structure layer.

### BACKGROUND OF THE INVENTION

1. Field of the Invention

The present invention relates to an optical functional film and a method of manufacturing the same. The optical functional film of the present invention is used in combination with a light emitting element emitting light.

2. Description of the Related Art

Conventionally, most flat panel displays have been liquid crystal displays which modulate the transmittance in combination with a light source. However, due to the problem of the response speed of the liquid crystal itself, the liquid crystal displays have been restricted in performance as displays for displaying animated images. Meanwhile, in competition with the liquid crystal displays in performance and price, various self-luminous type displays have been developed. As a display which can compete with the liquid crystal displays in performance and price, an organic EL (Electro Luminescence) display is a subject of interest now.

The organic EL display is a display element having an organic EL light emitting element configuration which has one or more organic electro luminescence material layers between two electrodes. In this display element, for every display unit constituting a display image, in other words, for every pixel, the organic EL light emitting element configuration is independently formed in a matrix form on a substrate surface.

This element is classified into an active type element or a passive type element in accordance with the driving method. The active type element includes an activation element having a 2-terminal or 3-terminal configuration for every picture element. In the passive type element, pixels required for light emission are individually driven by a longitudinal electrode and a transverse electrode which cross each other. The passive type element is used as a sub display of recent mobile phones.

In accordance with the light extraction method, the organic EL display is classified into a bottom emission type configuration in which light is extracted from a substrate side or a top emission type configuration in which light is extracted from a side opposite the substrate. In the bottom emission type configuration, at least the electrode on the substrate side of the two electrodes is a transparent electrode, and the other electrode is light reflective or has a light reflective layer provided outside thereof. Compared to this, in the top emission type configuration, the position of the transparent electrode and the light reflective layer is reversed, that is, the reflective layer is formed on the substrate side.

Generally, light emitted from a fluorescent material in a light emitting layer is output around the fluorescent material in all directions. Light output to a side opposite to a display surface is mirror-reversed by a reflector plate (typically, a reflection electrode) provided in a light path of the light output to the side opposite to the display surface. As a result, the light output in all directions can be extracted in the direction of the display surface. In course of that, the light penetrates through a plurality of layers (hereinafter also referred to as “media”), such as a cathode, a hole-transporting layer, an electron-transporting layer, an anode, a blocking layer, and a glass substrate, having different functions, and then is output to the air.

Here, on an interface between different media, the relationship between the refraction angle of light and the refractive index of the media follows Snell's law. According to Snell's law, when light penetrates from a medium having a refractive index of n1 into a medium having a refractive index of n2, the relationship n1×sin θ1=n2×sin θ2 holds true between an incidence angel θ1 and a refraction angle θ2. If n1 is greater than n2, the incidence angle θ1=sin−1(n2/n1) which realizes the relationship θ2=90° is well known as a critical angle. If the incidence angle is greater than the critical angle, the light experiences total internal reflection on the interface between the media.

Therefore, in the organic EL element isotropically outputting light, incident light on an interface between one layer and another layer being adjacent to said one layer at an angle greater than the critical angle experiences total internal reflection on the interface, and can not enter into the adjacent layer. The light which can not enter into the adjacent layer repeatedly experiences total internal reflection and is confined in said one layer.

This means that in the course of penetration through the plurality of layers in the element, part of light emitted from the light emitting layer is not output to the outside but confined in the element, which results in a cause to decrease apparent luminosity. Generally, it is known that most of emitted light from the light emitting layer of the organic EL element is confined in the element due to the total internal reflection, and effective emitted light is about 17% to 20% of all of the emitted light (see, for example, Advanced Material 6(1994)491).

In almost all self-luminous elements currently used as, for example, a luminous element, a light source, and a display element, light exists which impinges from a light emitting layer to a layer adjacent to the light emitting layer at an angle greater than or equal to the critical angle, and thus the light includes a component which can not be extracted as light. Examples are a fluorescence tube in which a fluorescent dye is excited by near ultraviolet light or ultraviolet light to emit light, and the light is output penetrating through a glass; a CRT (cathode-ray tube) in which a fluorescent dye is excited by an electron beam to emit light, and the light is output penetrating through a glass; an FED (field emission display apparatus) in which a fluorescent dye is excited by an electron beam from a micro site to emit light, and the light is output penetrating through a glass; a PDP (plasma display panel) in which a fluorescent dye is excited by ultraviolet light generated by plasma excitation to emit light, and the light is output penetrating through a glass; an organic EL element in which the recombination of the electron-hole pairs in the organic material excites the material to emit light, and the light is output penetrating through, for example, an electrode or a glass; an inorganic EL element in which the recombination of the electron-hole pairs in the inorganic material excites the material to emit light, and the light is output penetrating through, for example, an electrode or a glass; an LED (light emitting diode) in which the recombination of the electron-hole pairs at a pn-junction surface in a semiconductor material excites the emission of light, and the light is output penetrating through a resin layer; and especially a white or blue LED in which a fluorescent dye is excited by LED light emission within a near ultraviolet range to emit light, and the light is output penetrating resin.

In the self-luminous elements, conversion of energy to light in a light emitting portion is inherently restricted by, for example, a light emission mechanism, a material, or an element configuration. For example, in the method of converting the energy of invisible light into visible light by means of the fluorescent material, the efficiency of converting energy to light by the fluorescent dye is limited, the amount of dyes which can be arranged in a unit area is limited, and also the thickness in which excitation energy can enter is restricted. Therefore, concerning one kind of dye, the amount of light which can be extracted in a unit area shows such a characteristic that the amount has the maximum value when the density and the thickness of the fluorescent dye, which are variables, have certain values.

Moreover, the organic EL element has various restrictions due to, for example, an element configuration, a used organic material, or an electrode configuration. Moreover, the quantum efficiency of electroluminescence is limited. In the current organic EL element, it is necessary to increase the density of current flowing into an organic EL layer in order to increase the luminance in the light emitting layer. However, when the density of the current is increased, the degradation of the organic EL layer starts at an earlier stage, and the luminance rapidly decreases over time. Therefore, the problem arises that the lifetime of the element shortens if the priority is put on the brightness of the display, and it is not possible to increase the luminance by actually increasing the density of the current.

Furthermore, it is true for the actual self-luminous element that not all light emitted from the light emitting layer can not be utilized. This is due to such a phenomenon that when light is emitted from a medium having a refractive index of greater than or equal to 1 and incidence of the light occurs from a higher refractive index layer to a lower refractive index layer, part of the light has an angle greater than or equal to the critical angle. Such light experiences total internal reflection on an interface, so that the part of the light can not penetrate through the interface and can not enter into the lower refractive index layer.

Descriptions are given with reference to organic EL as an example. Layers constituting an element include, for example, a light emitting layer, a transparent electrode layer, and an element substrate, and each of the layers has a higher refractive index of 1.5. Therefore, light produced in the light emitting layer and output spatially in all directions experiences total internal reflection on interfaces between such layers that constitute the element and differ in refractive index by more than or equal to 0.1 (especially, on an interface between an electrode for driving and the element substrate, and on an interface between the element substrate and the air). Such light can not be extracted as a guided wave component. This phenomenon likewise occurs in an inorganic EL device or a semiconductor device whose light emitting portion is a layer having a refractive index of greater than or equal to 1.5, or in an element which is formed on a substrate and uses, for example, a fluorescent dye having a refractive index of greater than or equal to 1 to convert near ultraviolet light or ultraviolet light generated in the element to visible light. Assuming that the refractive index of the light emitting layer is nE, and the refractive index of the atmosphere into which the light is output is nA (usually air which has a refractive index of about 1), the approximation of the utilization efficiency of light is indicated by [Arcsin(nA/nE)/90]̂2. Therefore, as long as light is output from a liquid or a solid, it is difficult to obtain the light intensity efficiency greater than 32% (which is an approximate value of the extraction efficiency to the air from the water having a refractive index of 1.3).

Various propositions have been made to effectively use the energy converted into light in the self-luminous element such as an LED or an organic EL element. Especially, under such circumstances that the luminosity is restricted due to a material and an electrode configuration, various element configurations have been proposed in which the light extraction efficiency is improved in order to enhance the quality and the lifetime of the element. A configuration generally called scattering layer refers to a configuration in which particles within a range of sub-micron (about 0.5 μm) to micron (about 100 μm) are dispersed in a transparent medium having a certain refractive index. The layer thickness is required to be greater than or equal to the diameter of the dispersed particles in order to obtain a scattering characteristic.

A current high resolution display has a small distance of approximately 10 μm between pixels, and thus a thicker scattering layer leads to a haze in a pixel boundary and bleeding or blurring of display. Moreover, since microparticles themselves, which is dispersed as scattered materials are not perfect reflectors, attenuation also occurs due to absorption of light as well as scattering of light in the course of penetration of light through such scattered materials. As described above, in the conventional element adopting the scattered materials, improvement of the light extraction efficiency and the loss of light in the element are conflicting matters, and thus the extraction efficiency is not dramatically improved.

An element having an air space has been proposed as an example of a configuration having a lower refractive index layer arranged close to a light emitting layer (see Patent Document 1: Japanese Laid-Open Patent Publication No. 2003-45642). In this configuration, if an interface were completely flat, total internal reflection would occur in the course of outputting light from the light emitting layer to the air space, and thus the extraction efficiency would not be improved. Specifically, in Patent Document 1, the air space is formed by etching a sacrifice layer formed on a substrate, and thus the interface between the light emitting layer and the air space is not completely flat but has random concavities and convexities. This achieves a condition in which part of light has an angle smaller than or equal to the critical angle while the light being guided, and the part of the light is extracted as guided light into the air space. Therefore, in the organic EL element of Patent Document 1, the amount of extracted light is not always over the restriction by the critical angle but the extraction efficiency is only improved locally.

A configuration has been proposed in which the extraction efficiency is improved by a silica aerogel layer (see Patent Document 2: Japanese Laid-Open Patent Publication No. 2003-77647). However, a configuration of a silica aerogel is not clear. Generally, it is thought that a silica gel of a net-like porous silica gel membrane whose mesh is smaller than or equal to the wavelength changes into a silica, so that the volume of a net portion constituting the net decreases while a nano-order interval of the mesh remains the same, which results in an increased pore diameter. Such membrane having a high porosity is effective as one of approaches to realize an optically low refractive index, but has problems relating to processes and the structure itself. Examples of the problems are (1) it is difficult to control a mesh configuration of the initial silica gel; (2) a high process temperature is required to change the silica gel into the silica; (3) there are many restrictions on the subsequent steps of forming and patterning a film due to the high porosity; and (4) a mechanical strength is weak. Although it is reported that an element provided with an aerogel layer has a higher light extraction efficiency, the controlling to actively improve the efficiency and an improving means are not explained. Since the light extraction efficiency is improved by effects derived only from a particular structure, i.e. the silica aerogel, applicable devices are limited.

Patent Document 3 (Japanese Laid-Open Patent Publication No. 2003-100458) discloses a light emitting apparatus including an optical member which has micro beads in a predetermined arrangement. According to this light emitting apparatus, the micro beads are regularly arranged such that the optical member forms a photonic band gap or an imperfect photonic band, so that the luminosity can be improved. The light emission achieved by the light emitting apparatus has a high directivity, and thus a high luminance is obtained in the normal direction to a substrate surface. However, a problem arises that the luminance drastically lowers in a direction slightly deviating from the normal direction.

In technology for LEDs but not for organic EL, it has been proposed to form a nanometer size concavo-convex configuration on a surface of an element to increase the extraction efficiency (see Patent Document 4: Japanese Laid-Open Patent Publication No. 2003-258296). In this prior art, it is thought that three effects are derived from the nanometer size concavo-convex shape.

Firstly, there is an effect that providing a concavo-convex surface in nanometer size smaller than or equal to the wavelength continuously changes in the layer thickness direction the refractive index of a light path along which light is output from the layer having concavities and convexities to a layer adjacent thereto. The continuous change of the refractive index makes it possible to reduce the loss of light which occurs on an interface between layers greatly differing in refractive index. However, it is not possible to extract light which experiences total internal reflection when the light is output from a higher refractive index layer to a lower refractive index layer.

Secondly, an effect of the concavo-convex surface is mentioned. Due to the concavo-convex surface, an incidence angle of light to a very small area of the interface becomes smaller than or equal to the critical angle (becomes out of the condition of total internal reflection). However, a condition in which on one interface between two layers, the incidence angle to the concavo-convex surface in nanometer size smaller than or equal to a wavelength on a surface becomes less than or equal to the critical angle is filled only when the concavo-convex shape on the surface has a shape serving as a prism. Therefore, anisotropism of characteristics tends to occur due to the concavo-convex shape on the surface. In actual processes, it is technically demanding to form such concavo-convex surface in the nano order. In a surface processed according to energy dispersion of light or an electromagnetic wave or in a concavo-convex surface formed by an ordinary chemical process, it is difficult to arbitrarily control the profile. A whole interface considered, a region having a decreased efficiency is simultaneously formed, even if the profile could be realized in a very small part. This limits the amount of extracted light.

Thirdly, a light extraction effect due to an evanescent region of an interface is mentioned. It is classically and optically thought that in incidence of light from a higher refractive index layer to a lower refractive index layer, light whose incidence angle is greater than the critical angle experiences total internal reflection and can not enter into the lower refractive index layer. However, it is known that when light is taken as energy, there is a region at which the energy of the light can arrive inside the lower refractive index layer adjacent to the higher refractive index layer. This region is called evanescent region. If an object (specifically, an interface) which changes the vector of the energy of the light is provided in the evanescent region, the light is reflected or refracted on the interface, and thus the light path is changed, so that there is a component of light penetrates into the lower refractive index layer. However, in this prior art, there is only one interface between the two layers. Therefore, even if the light would penetrate as the energy through the interface and enter into the lower refractive index layer, there is low possibility that the light arrives at such an interface that changes the light path. Therefore, a sufficient light extraction effect in the evanescent region can not be expected.

As explained above, since the prior art adopts very limited configuration in which the concavo-convex configuration in nanometer order and smaller than or equal to the wavelength is formed close to the interface, only the effect “making the refractive index continuous” can be used for the light extraction.

### SUMMARY OF THE INVENTION

In order to overcome the problems described above, preferred embodiments of the present invention realize improvement of light extraction which is not greatly improved by existing techniques or prior arts and provide an element configuration which can improve the luminosity of extracted light without affecting characteristics of the self-luminous element.

In recent years, near-field light and various applications thereof have been investigated. As explained above, when light from a higher refractive index layer impinges on a lower refractive index layer, part of the light having an incidence angle exceeding the critical angle optically experiences total internal reflection on an interface between the two layers. Even in a case where the light under such incident condition impinges on the interface, there is a region (evanescent region or near-field region) in the lower refractive index layer into which light energy can enter from the interface between the higher refractive index layer and the lower refractive index layer. As the distance from the joint interface between the higher refractive index layer and the lower refractive index layer increases, as the incidence angle increases, or as the refractive index difference between the higher refractive index layer and the lower refractive index layer increases, the light energy in this region exhibits abruptly lowering behavior.

It is known that providing a structure for changing the course of light in the evanescent region allows extraction of the light energy according to the distance of the structure from the interface. It is assumed that light (having a wavelength of 450 nm) impinges on a medium having a refractive index of 1.0 (for example, air) from a medium having a refractive index of 1.5 (for example, a glass).

FIG. 1 is a graph illustrating the relationship between the distance from the interface and the energy (strength) of light, where the energy (strength) of light on the interface is 1. Plotted lines respectively show detectable (extractable) light energy depending on the distance from the interface for incidence angles of light on the interface. The plotted data can be obtained from a generally known formula for calculating energy of light in the evanescent region (near-field light) (see Motoichi Ohtsu, Kiyoshi Kobayashi, “Basics of Near-Field Light”, Ohmsha).

As shown in FIG. 1, about 15% or more of light energy on the interface enters in the region within a distance smaller than or equal to 100 nm from the interface. In other words, in the region within a distance smaller than or equal to 100 nm, light which can not be extracted due to the total internal reflection and the due to no incident component has energy as light. Therefore, if it is possible to change an output direction of light in a position where the light can exist as energy, the light corresponding to the energy in the position can be extracted.

In the present invention, this optical phenomenon is actively induced in the element to improve the light extraction efficiency. Specifically, the light emitting element of the present invention includes a light emitting layer emitting light such as visible light and an optical functional film (hereinafter referred to as “refractive index composite structure layer” or simply “structure layer”). The optical functional film is composed of a single layer or multiple layers arranged in a light path of the light output from the light emitting layer

The refractive index composite structure layer includes a refractive index composite structure (hereinafter referred to as simply “structure”) having characteristics (1) thorough (4) as follows: (1) an internal configuration includes two or more types of phases differing in refractive index; (2) at least one of the two or more types of phases includes a structural unit having a size greater than or equal to 1 nm and smaller than or equal to ¼ (100 nm, if the shortest wavelength of the visible light is 400 nm) of a wavelength within a visible light wavelength range; (3) an average refractive index of the structure is higher than 1 and lower than a refractive index of a plurality of layers between a light emitter and the optical functional film excepting a layer including a gas phase (which is preferably in a vacuum state or a lower pressure state than atmospheric pressure); and (4) the internal configuration in a thickness direction of the structure includes a plurality of interfaces between the two or more types of phases in a near-field region into which light as energy can enter from an interface between the optical functional film and another layer adjacent to the optical functional film. When the refractive index composite structure layer includes a single layer, the structure is formed close to an interface between the refractive index composite structure layer and another layer from which the light enters. When the refractive index composite structure layer includes multiple layers, the structure is formed in a layer on a side from which the light enters.

The size of the structural unit is preferably greater than or equal to 1 nm and smaller than or equal to 100 nm, and more preferably greater than or equal to 5 nm and smaller than or equal to 100 nm.

The structure may be a cellular structure formed of one of the two or more types of phases. In this case, the structural unit has a thickness of a wall constituting the cellular structure and/or a size of a gap between the wall constituting the cellular structure and another wall facing the wall constituting the cellular structure. The term “cellular structure” refers to a structure having spaces partitioned by a film structure such as a cell wall of a cell or foam of bubbles. Although a wall partitioning a cell typically does not have a hole, the wall may be provided with holes.

Note that in the present specification and claims, the wording “A and/or B” means “at least one of A and B”.

Alternatively, the structure may be a network structure formed of one of the two or more types of phases. In this case, the structural unit has at least one from the group consisting of a diameter of fibers constituting the network structure, a distance between the fibers, and a size of a gap formed by the network structure.

Alternatively, the structure may be a block-like structure which is formed of one of the two or more types of phases. In this case, the structural unit has a diameter of the block-like structure or a size of a gap between the block-like structures.

The structure includes at least two types of phases differing in refractive index. One of the at least two types of phases has a refractive index lower than the refractive index of the other phase. Hereinafter, the phase having a lower refractive index is referred to as a lower refractive index phase (first phase) and the layer having a higher refractive index is referred to as a higher refractive index phase (second phase). Note that in a case where the refractive index composite structure layer includes three or more types of phases, a phase whose refractive index is higher than the refractive index of the higher refractive index phase and a phase whose refractive index is lower than the refractive index of the lower refractive index phase can exist.

It is preferable that at least one phase (for example the higher refractive index phase) of the two or more types of phases has a characteristic which permits self-retaining the structure at least within a temperature range centering around ambient temperature in which an element operates. The term “self-retaining” means that a material itself can be formed into any shape and stably retains the shape in a still standing state within a certain temperature range (generally ambient temperature), and involves a case where the material actively forms a specific shape through self-organization for example. For example, the foam of bubbles does not have the characteristic which permits self-retaining, because the foam fades as time passes. Meanwhile, in an expanded polystyrene or an expanded urethane, a foam structure is formed with which any shape can be formed, while the porous structure in a still standing state does not collapse over time. Therefore, materials which can form such structure have the characteristic which permits self-retaining.

The higher refractive index phase is formed of a material whose refractive index is higher than that of a material for the lower refractive index phase. It suffices that the refractive index of the higher refractive index phase is higher than the refractive index of the lower refractive index phase. However, it is preferable that the higher refractive index phase has a refractive index higher than or equal to 1.3.

To the lower refractive index phase, a solid phase, a liquid phase, or a gas phase is applicable, the solid phase, the liquid phase, or the gas phase having a refractive index lower than the refractive index of a glass, a resin, a silicon, or the like, which is generally used as a substrate material. The refractive index of the lower refractive index phase is typically lower than or equal to 1.4, and preferably close to 1. Specifically, the refractive index of the lower refractive index phase is lower than or equal to 1.2 and more preferably lower than or equal to 1.1.

The solid phase is, for example, a compound or a polymer whose refractive index is lowered. Examples are a compound having a lower electron density whose molecular structure includes many fluorine atoms as hetero atoms (for example, a compound (monomer) having a fluorine-substituted alkyl chain); a compound which is voluminous in space and does not increase in density due to the three dimensional bonding structure of molecules (for example, fullerene C60); and a compound which exhibits volume shrinkage resulting from a chemical reaction of the compound without changing the space filling condition (for example, silica having a network structure obtained by thermal treatment of a porous silica gel configuration). Using such a compound or a polymer, the refractive index, which is a physical property value is lowered.

The liquid phase is, for example, a liquid composition having a refractive index between about 1.3 and about 1.4. Examples are water which has a high phase separation degree from a resin material retaining the structure, and whose wettability to the resin material can be controlled; a solution in which, for example, a surfactant is added for a better phase separation degree; and a low-molecular compound or a composition having a fluorine-substituted alkyl chain.

Examples of the gas phase are air, gas, and vacuum. The gas phase has a refractive index of about 1, and thus the gas phase is preferable as a lower refractive index phase in terms of the light extraction efficiency.

Examples of a method of producing the structure are a method in which micro particles are used and a method of generating bubbles having a nanometer size in a block polymer or a resin composition which can perform the self-organization. Depending on manufacturing processes, a solid, fluid, or gas state is applicable. For example, in a case where a gas phase is used as a lower refractive index phase, following methods are conceivable as a method of forming the gas phase.

1. Randomly stacking space-occupying bodies (for example, particles) produces gaps between the space-occupying bodies, and each gap is used as a lower refractive index phase.

2. Randomly stacking space-occupying bodies containing a bubble (for example, particles) produces gaps between individual space-occupying bodies, and each gap is used as a lower refractive index phase.

3. Two or more types of domains differing in physical property are formed in a self-organizing manner, then one or more (but not all) domains of the two or more types of domains are selectively eliminated by utilizing the difference in etching speed or solubility. This produces space which is to be used as a lower refractive index phase.

4. In a resin material, micro bubbles smaller than or equal to the order of micro meter are generated. The diameter of the micro bubbles is controlled by any factors to form a lower refractive index phase in the nano order size.

When a liquid phase is used as the lower refractive index phase, a liquid phase part is formed, for example, by a micelle structure formation method (so-called micelle formation or emulsification) by mixing liquids having no compatibility (for example, mixing of water and oil). However, since controlling a particle diameter is very difficult in an ordinary micelle formation method or emulsification method, it is preferable to adopt various methods recently developed. For example, it is desirable to adopt a technology of micelle formation in the form of liquid phase particle by using SPG (Shirasu Porous Glass) or a microencapsulation technology. In the microencapsulation technology, liquids having no compatibility are dropped from a micro nozzle to form liquid drop domains, the domains are stabilized, and surfaces of the liquid drop domains are processed to prevent the recombination of the domains. In a method, a micro particle dispersion solution is prepared by such a process that has a wide particle size distribution generally due to reaction control when the formation of the particles is completed. Even in such a method, it is possible to adopt a “separation technique” for extracting a micro liquid phase having a certain particle diameter distribution width in order to prepare a micro particle dispersion solution which has a targeted particle diameter and particle diameter distribution. An example of the method is emulsion polymerization in which accurate control of the particle diameter is difficult.

When a solid phase is used as the lower refractive index phase, a solid phase part is formed, for example, by a method of micrifying at the time of solidification, or a method in which a big particle is subjected to a crushing process to produce micro particles. An example of the method of micrifying at the time of solidification is a method in which a polymeric compound is made into a micro liquid phase by the method of producing the micro liquid phase, and the micro liquid phase in this state is polymerized for solidification.

As described above, various methods of producing the lower refractive index phase are possible in each phase state, i.e., solid, liquid, or gas. Performance of the structure itself differs depending on which phase state is adopted.

If a solid or liquid phase state is adopted, it is difficult to lower the refractive index of the lower refractive index phase. However, since both of the solid phase and the liquid phase are incompressible, the structure has a high strength against the pressure exerted from the outside. Meanwhile, if a gas phase state is adopted, the optimum extraction efficiency can be obtained. However, there is a disadvantage that the strength of the structure itself reduces.

As described above, since a state of the lower refractive index phase determines a formation method and a function of the lower refractive index phase, it is possible to accordingly select the state or the process for the lower refractive index phase according to the performance required to a targeted device.

Since the structure includes a structural unit (for example, hole or bubble) having a size smaller than or equal to the wavelength of visible light, the refractive index of the structure itself can be identified with the average refractive index of the refractive index composite structure layer. Moreover, since the structural unit (for example, hole or bubble) is provided inside the structure, a number of micro interfaces between phases differing in refractive index are formed in the refractive index composite structure layer.

When light passes through the number of micro interfaces, penetration/reflection occurs on individual micro interfaces. While light penetrates through the structure, distribution of output azimuthal energy is randomized even if the penetration occurs in a short distance, and thus the effect similar to the light scattering can be induced very efficiently. Note that the phenomenon is different from the effect obtained by a scattered material in one point that a general scattered material causes two phenomena, i.e., scatter reflection and absorption, and it is very difficult to reduce the absorption itself caused by the scattered material to zero.

Meanwhile, in the structure of the present invention, while light travels from one interface to another interface, the light penetrates through a high refractive index or low refractive index phase (medium). However, the length of a light path along which the light penetrates in the medium is shorter than or equal to 1 μm in the structure of the present invention and thus can be ignored. Therefore, it is possible to assume that “no absorption” occurs while the light penetrates through a medium having a refractive index, and it is possible to consider only the “reflection” and “refraction” on an interface. As a result, a phenomenon which occurs in the general scattered material, specifically, the phenomenon that the increasing layer thickness attenuates light which can be extracted, hardly occurs.

In a case where the structure layer is adjacent to a higher refractive index layer or between the higher refractive index layers, the structure enables the extraction of evanescent light. Specifically, energy produced in the evanescent region (near-field region) close to an interface between the higher refractive index layer and the structure layer can be extracted as light. Moreover, in the evanescent region, light penetrates through a plurality of micro interfaces of a plurality of micro structures (for example a refractive index composite structures formed of air and a higher refractive index medium), which randomly scatters a light path. This converts the light energy to light which can penetrate through the structure layer, thereby the amount of light which is extracted from the element increases.

Optically, the light scattered inside the structure can be substantially identified with light output from a layer having the average refractive index of the structure. Therefore, an effect can be obtained that light from the higher refractive index layer (for example, light emitting layer) can be identified with light emitted from the layer having the average refractive index of the structure. This effect increases the amount of light which can be extracted, the light being emitted from the light emitting layer. The average refractive index of the structure is lower than the refractive index of the resin material, which is the solid phase forming a porous body structure layer (refractive index composite structure layer). Moreover, since the structure includes the plurality of micro interfaces, it is possible to significantly improve the light extraction efficiency.

In case of a light emission type device, the higher refractive index layer has a refractive index of greater than or equal to 1.4. Examples of the higher refractive index layer are a light emitting layer (having a refractive index between 1.5 and 1.8) itself for organic EL, an electrode (having a refractive index between 1.8 and 2.0), an n-channel layer or a p-channel layer (having a refractive index greater than or equal to 1.5) of a semiconductor device in an LED, a fluorescent material (having a refractive index greater than or equal to 1.5) which emits visible light by ultraviolet light, such as an electrode material, a fluorescent lamp, or a PDP. Especially in a self-luminous type device (excepting an incandescent lamp), a light emitting section and a layer contributing to light emission have a refractive index greater than or equal to 1.5.

To increase the light extraction efficiency, it is effective to provide the porous body structure layer (refractive index composite structure layer) in a light path along which light emitted from a light emitting layer. However, as to loss of light incident on interfaces in the light path, the closer to the visible light emitting layer the porous body structure layer is provided, the more the amount of light which can be extracted increases. Especially in case of organic EL or inorganic EL, if the light emitting layer is configured as a porous body structure, the extraction efficiency of emitted light increases. Therefore, a configuration having the porous body structure layer (refractive index composite structure layer) between an electrode and a light emitting layer, in other words, a configuration having the structure between higher refractive index layers is adopted.

As a method of applying the present invention to an actual element, various methods can be adopted. For example, in case of a structure formed of a gas and a polymer, it is possible to adopt methods as follows.

Method 1. Micro particles having an aimed unit structure is applied as targets on a light emitting element substrate, and then the particles are bonded to each other and to the substrate.

Method 2. Aimed unit structures are formed by self-organization or phase separation, and then one of the structures is removed using a difference in etching rate or in dissolution rate.

Method 3. A reaction of the polymeric resin material is caused to form a micellar state in which a mixed solution of the polymeric resin material and an appropriate non-polymeric solvent having no phase compatibility is emulsified. Then, the non-polymeric solvent is vaporized from a structure formed by polymerization of the resin material in order to produce a porous structure.

Method 4. Micro bubbles are generated in a resin before curing, the bubbles being greater than or equal to 1 nm and smaller than or equal to 0.1 μm. Then, the resin is cured with the bubbles stably dispersed.

In order to actually form an element, it is required that the light emitting layer itself, a peripheral member supporting the light emitting element, or a member supporting the refractive index composite structure layer has resistance to solutions or process conditions used in the course of forming the refractive index composite structure specified in the present invention. Therefore, if the resistance of the light emitting layer itself, the peripheral member supporting the light emitting element, or the member supporting the refractive index composite structure layer is unclear or insufficient, it is also possible to form the element by one of the methods a) through d) as follows.

a) One or more protection layers having the resistance to solutions or process conditions used in the course of forming the refractive index composite structure are formed on the light emitting layer, the light emitting element, a peripheral member constituting the light emitting element, or the member supporting the refractive index composite structure layer. Then, steps of forming the refractive index composite structure specified in the present invention are performed.

b) In order to enable detachment of a structure which is to be formed, a surface process is performed on a substrate having the resistance to solutions or process conditions used in the course of forming the refractive index composite structure. Then, steps of forming the refractive index composite structure specified in the present invention are performed to form a structure layer on the substrate. Then, the formed structure layer is detached from the substrate, and then put on the light emitting layer, the light emitting element, the peripheral member supporting the light emitting element, or the member supporting the refractive index composite structure layer for tight attachment.

c) Steps of forming the refractive index composite structure specified in the present invention are performed to form a structure layer on a substrate having the resistance to solutions or process conditions used in the course of forming the refractive index composite structure. Then, the formed structure layer with the substrate is fixed on the light emitting layer, the light emitting element, the peripheral member supporting the light emitting element, or the member supporting the refractive index composite structure layer.

d) After the fixation of the structure layer with the substrate by method c), the substrate is removed.

Alternatively, depending on elements, before the light emitting element is formed, the refractive index composite structure specified in the present invention is formed. This makes it possible to perform a light emitting element formation process on the substrate having the refractive index composite structure. In this case, it is required for the refractive index composite structure itself specified in the present invention to have the resistance to solutions or process conditions used in the light emitting element formation process. For example, the formation according to one of a procedure A) and a procedure B) as follows is possible.

A) A refractive index composite structure specified in the present invention is formed. Then, one or more protection layers are formed on the refractive index composite structure having the resistance to solutions or process conditions used in the light emitting element formation process. Then the light emitting element formation process is performed.

B) A refractive index composite structure specified in the present invention is formed on a rear surface of a substrate used in the light emitting element formation process. On the surface of the substrate on which the refractive index composite structure is formed, one or more protection layers are formed or a protection substrate is fixed, the protection layer or the protection substrate having the resistance to solutions or process conditions used in the light emitting element formation process. Then, the light emitting element formation process is performed.

As the above mentioned protection layer or the protection substrate, a member suitable for processes of the respective devices can be adopted according to a respective required process resistance. For example, an inorganic film such as a thin glass, a high denseness SiN, SiONx, or SiO2, or an organic-type film such as a polymeric film or a polymer film can be adopted.

If a visible light emitting portion is a fluorescent material such as a fluorescent dye, it may be preferable to change the element configuration according to an excitation energy source used for emission of the visible light from the fluorescent material. For example, when invisible light (generally light within a range of ultraviolet to near ultraviolet) is used to excite the element (for example, a fluorescent tube or a PDP), it is required that excitation light itself efficiently impinges on the fluorescent material. Generally, light produced by discharging electrons in a gas, for example, in a fluorescent lamp or the excitation light produced by plasma, for example, in a PDP is light emitted in a vacuum or in a reduced-pressure atmosphere, and thus can be viewed as light emitted from a layer having a refractive index of 1. When light impinges on a layer having a refractive index greater than or equal to 1 from the layer having a refractive index of 1, there is no condition of critical angle, and thus an incidence of the light produced in the gas is possible with a high efficiency. Meanwhile, between two layers differing in refractive index, the greater the incidence angle is, and the higher the refractive index of the two layers is, the more the injection efficiency of light reduces.

Also in such configuration, the refractive index composite structure specified in the present invention can function effectively. The reason for this is that when the light produced in the gas impinges on the refractive index composite structure specified in the present invention, the light incidence is possible without total internal reflection due to the critical angel and without reducing the light injection efficiency due to a great difference in refractive index. This is because the refractive index of the refractive index composite structure is higher than the refractive index of a gas phase but sufficiently lower than the refractive index of the fluorescent material.

Meanwhile, since on an interface between a fluorescent material layer and the refractive index composite structure specified in the present invention, the refractive index of the fluorescent material is higher than the refractive index of the refractive index composite structure, the total internal reflection due to the critical angel does not occur. Moreover, as to the difference in refractive index, the refractive index of the refractive index composite structure has a value at least between the refractive index of the fluorescent material and the refractive index of the gas phase. Therefore, the difference in refractive index between the fluorescent material and the refractive index composite structure is smaller than the difference in refractive index between the fluorescent material and the gas phase, and thus the light injection efficiency is improved.

In the refractive index composite structure of the present invention, controlling structure distribution inside the refractive index composite structure makes it possible to lower the refractive index of the structure close to a side from which the light enters and to increase the refractive index of the structure close to a side from which the light is extracted. Therefore, realizing the configuration having a lowered refractive index of the structure layer close to the gas phase and an increased refractive index of the structure layer close to the fluorescent material allows the excitation light produced in the gas phase to impinge on the fluorescent material with a minimum loss.

Examples of factors which allow controlling the internal configuration of the refractive index composite structure are particles, bubbles and spontaneous phase separation in the methods described above used for forming the structure of the present invention. In addition to forming the structure as a homogeneous layer, if a process condition (for example, bubble generation condition (such as a particle diameter, a gas pressure, or a flow speed which are used) or a temperature for phase separation) is changed during the process, the structure which is to be formed can be controlled in a certain range.

As described above, also in an element in which the excitation light is produced in the gas phase, it can be expected that using the refractive index composite structure improves the incident efficiency of excitation light on the fluorescent material and contributes to improvement of the efficiency of converting energy to light in the light emitting element.

Exemplary element configurations of a refractive index composite structure applicable to an actual device are shown in FIG. 2 through FIG. 5.

FIG. 2 shows configuration examples in devices using external excitation light for fluorescent emission, and the configuration is applicable to a light emitting configuration in an actual device such as a fluorescent tube or a PDP. In the devices shown in FIG. 2, a fluorescent material is exposed to invisible excitation light generated in a vacuum or in a gas for emitting visible light. FIG. 2A1 and FIG. 2A2 show reflection-type configuration examples, and FIG. 2B1 and FIG. 2B2 show penetration-type configuration examples. In these drawings, a reference number 1 refers to a substrate, a reference number 2 refers to a reflection film (reflector plate or reflection layer), a reference number 4 refers to a fluorescent material layer containing a fluorescent dye, reference numbers 5 and 5′ refer to refractive index composite structure layers of the present invention, a reference number 6 schematically shows an incidence direction (in practice, including various incidence angle components) of energy (excitation light) which excites the fluorescent material layer (4), and a reference number 7 schematically shows an output direction (in practice, including various output angle components) of light which is to be extracted (output light).

FIG. 2A1 shows the configuration example where the refractive index composite structure layer (5) is formed over the substrate (1) for supporting an element configuration. FIG. 2A2 shows the configuration example which can be realized in a case where one of the reflection film (2), the fluorescent material layer (4) containing the fluorescent dye, and the refractive index composite structure layer (5) which are constituting the element has a sufficient strength for retaining the element configuration and its shape. For example, as the reflection film (2), a metal film is generally used. However, if a metal plate itself is used as the substrate, the metal plate can support the configuration, and thus it is not necessary to further provide a substrate for supporting the element configuration.

The refractive index composite structure of the present invention serves to improve the incidence efficiency in incidence of the excitation light. In the reflection-type configuration, this refractive index composite structure can also contribute to improve the extraction efficiency of light when the light is output. Therefore, sufficient improvement in characteristics can be expected by providing one refractive index composite structure layer. Although it is not shown, a configuration is also possible which has the refractive index composite structure (5) provided between the reflection film (2) and the fluorescent material layer (4).

FIG. 2B1 shows the configuration example in which the refractive index composite structure layer (5) is formed over the substrate (1) for supporting the element configuration. FIG. 2B2 shows the configuration example which can be realized in a case where one of the fluorescent material layer (4) and the refractive index composite structure layer (5) which are constituting the element has a sufficient strength for retaining the element configuration and its shape. For example, the refractive index composite structure layer (5) may be provided on a surface of or in a bulk of a plate material (for example, resin substrate) which can support the element configuration. In this case, it is not necessary to further provide a substrate for supporting the element configuration.

However, in order to achieve the object of increasing the incidence efficiency of the excitation light (6) and the object of improving the extraction efficiency of the output light (7) from the fluorescent material layer (4), two refractive index composite structure layers (5) and (5′) are required.

Effects of improving the extraction efficiency of light from the fluorescent material layer (4) in this configuration differ depending on the distance along which light is guided, and the distance along which light is guided in FIG. 2B1 is the fluorescent material layer (4), refractive index composite structure layer (5′), and the substrate (1), and the distance along which light is guided in FIG. 2B2 is the fluorescent material layer (4) and refractive index composite structure layer (5′). As explained with reference to FIG. 2A1 and FIG. 2A2, considering the effect of apparently reducing the refractive index of a light emitting region by the refractive index composite structure layer (5′) itself and the effect of apparently scattering, sufficient improvement of the light extraction efficiency can be expected. Note that, if the excitation light (6) itself damages the refractive index composite structure and cause performance deterioration, a structure may be possible which is not provided with the refractive index composite structure (5′) as shown in FIG. 3B1 and FIG. 3B2.

FIG. 3 shows configuration examples in devices using external excitation energy for fluorescent emission, and the configuration is applicable to an element adopting emission of light from a fluorescent material excited by an electron beam as an actual device. The configuration is used, for example, in part of a general CRT, FED (Field Emission Display), or PDP. In the device shone in FIG. 3, a fluorescent material is exposed to an energy beam for exciting the florescent material in a vacuum or in a gas for emitting visible light. FIG. 3A1 and FIG. 3A2 show reflection-type configuration examples, and FIG. 3B1 and FIG. 3B2 show penetration-type configuration examples.

This configuration is to be adopted in a case where direct exposure of the fluorescent material layer (4) to the excitation energy beam is preferable to increase the luminosity of the fluorescent material layer (4) or in a case where the excitation energy beam damages the refractive index composite structure itself.

FIG. 3A1 shows the configuration example in which the refractive index composite structure layer (5) is formed over the substrate (1) for supporting the element configuration. FIG. 3A2 shows the configuration which can be realized in a case where one of the reflection film (2) constituting the element, the fluorescent material layer (4), and the refractive index composite structure layer (5) has a sufficient strength for retaining the element configuration and its shape. For example, as the reflection film (2), a metal film is generally used. However, if a metal plate itself is used as the substrate, the metal plate can support the configuration. Therefore, it is not necessary to further provide a substrate for supporting the element configuration.

In this case, the refractive index composite structure layer (5) is provided between the reflection film (2) and the fluorescent material layer (4). Also in this configuration, a sufficient effect can be expected for extracting the light (7) emitted from the fluorescent material layer (4). The reason for this may be as follows. Light emitted from the fluorescent material layer (4) excepting light component directly output from the fluorescent material layer (4) is guided between the fluorescent material layer (4) and the refractive index composite structure layer (5) and between the refractive index composite structure layer (5) and the reflection plate (2). Inside the refractive index composite structure, the effect of improving the light extraction efficiency in the near-field can be obtained in a location close to an interface between the fluorescent material layer (4) and the refractive index composite structure layer (5). Moreover, since the structural unit of the refractive index composite structure is smaller than or equal to the wave length, the extracted light can be used equivalently to the light output from a layer having the average refractive index of the refractive index composite structure. Therefore, the light penetrating through the extraction region is converted into light which can be output at a constant rate from the fluorescent material.

Moreover, it is possible to increase the amount of light which can be extracted from the fluorescent material layer (4) by controlling the internal configuration of the refractive index composite structure itself to enhance a light scattering characteristic. Therefore, also in the configurations shown in FIG. 3, a sufficient effect of improving the light extraction efficiency can be expected.

FIG. 3B1 shows the configuration example in which the refractive index composite structure layer (5) is formed on the substrate (1) for supporting the element configuration. FIG. 3B2 shows the configuration example which can be realized in a case where one of the fluorescent material layer (4) constituting the element and the refractive index composite structure layer (5) has a sufficient strength for retaining the element configuration and its shape. For example, the refractive index composite structure layer (5) may be provided on a surface of or in a bulk of a plate material (for example, resin substrate) which can support the element configuration. In this case, it is not necessary to further provide a substrate for supporting the element configuration.

Effects of improving the extraction efficiency of light from the fluorescent material layer (4) in this configuration differ depending on the distance along which light is guided, and the distance along which the light is guided in FIG. 3B1 is the fluorescent material layer (4), refractive index composite structure layer (5), and the retention substrate (1), and the distance along which the light is guided in FIG. 3B2 is through the fluorescent material layer (4) and refractive index composite structure layer (5). As explained with reference to FIG. 3A1 and FIG. 3A2, considering the effect of apparently reducing the refractive index of a light emitting region by the refractive index composite structure layer (5) itself and the scattering effect, sufficient improvement of the light extraction efficiency can be expected.

FIG. 4 shows configuration examples of devices each of which is combined with a self-luminous type element from which light is directly extracted. The configuration is used for a general semiconductor LED, organic EL, or inorganic EL. In FIG. 4, a reference number 3 refers to a self-luminous layer (note that, the actual device portion is not shown). FIG. 4A1 and FIG. 4A2 show configuration examples of elements which are often applied to the organic EL or the inorganic EL. Each element includes the self-luminous layer (3) and the reflection layer (2) adjacent to the self-luminous layer (3). In practice, a configuration is possible in which any film or structure is provided between the self-luminous layer (3) and the refractive index composite structure layer (5) of the present invention, but the drawings thereof are omitted. Moreover, the self-luminous layer (3) is a structure constituted of one or more layers including an electrode for driving the self-luminous layer (3), but the structure thereof is omitted in FIG. 4. FIG. 4B1 and FIG. 4B2 show configurations which are often applied to the semiconductor LED. In these configuration examples of the elements, the substrate itself constituting the self-luminous layer (3) is nontransparent, or the electrode constituting the self-luminous layer (3) has a light reflection function. Moreover, The elements in FIG. 4A1 and FIG. 4A2 are configuration examples where the refractive index composite structure layer (5) has not a sufficient strength, and thus an optically transparent substrate (1′) is provided for protecting the refractive index composite structure layer (5). The elements in FIG. 4A2 and FIG. 4B2 are configuration examples where the refractive index composite structure layer (5) has a sufficient strength.

FIG. 5 shows configuration examples in devices in which as excitation light, light output from a self-luminous type element is used whose luminous wavelength is converted by, for example, a fluorescent dye, and the converted light is used for displaying. The configuration examples in FIG. 5 are used for an LED, organic LE, or inorganic EL, and provided with the self-luminous layer (3), a light wavelength conversion layer (14), and the refractive index composite structure layer (5). For example, the self-luminous layer (3) performs single-color light emission, and the light wavelength conversion layer (14) converts a color of the light emitted from the self-luminous layer (3) to different colors for displaying in multiple colors or to light having a specific wavelength.

In these configurations, the refractive index composite structure layer (5) serves to improve two efficiencies, which are the injection efficiency of light from the self-luminous layer (3) to the light wavelength conversion layer (14) and the extraction efficiency of light output from the light wavelength conversion layer (14). Since the light extraction includes outputting light into the air, it is preferable to provide the refractive index composite structure layer (5) in a light path along which light travels from the light wavelength conversion layer (14) to the air in order to improve the extraction efficiency of the light output from the light wavelength conversion layer (14).

Meanwhile, when the refractive index of the light wavelength conversion layer (14) is substantially equal to or higher than the refractive index of the self-luminous layer (3), it is not always necessary to provide the refractive index composite structure layer (5′) in order to improve the injection efficiency of light from the self-luminous layer (3) to the light wavelength conversion layer (14) as shown in FIG. 4A1 and FIG. 4A2. However, when the refractive index of the light wavelength conversion layer (14) is lower than the refractive index of the self-luminous layer (3), the configuration having the refractive index composite structure layer (5′) as shown in FIG. 4B1 and FIG. 4B2 is desirable for eventually improving the light extraction efficiency.

The elements of FIG. 5A1 and FIG. 5B1 are configuration examples of a case where the refractive index composite structure layer (5) has an insufficient strength, and thus the optically transparent substrate (1′) is provided for protecting the refractive index composite structure layer (5). The elements of FIG. 5A2 and FIG. 5B2 are configuration examples of a case where the refractive index composite structure layer (5) has a sufficient strength.

Note that, according to a configuration and function of the element, a configuration is possible which does not necessitate the reflection film (2). Such configuration without the reflection film (2) can be easily conceived by referring to the configurations of FIG. 2B1, FIG. 2B2, FIG. 3B1, FIG. 3B2, FIG. 4B1, and FIG. 4B2, and thus the drawings thereof are omitted.

Effectiveness of the present invention is not limited only to a device (element) newly formed according to the invention. The effectiveness includes that the present invention permits retrofitting to existing devices. For example, the present invention also provides a film or a plate-like member which is to be stuck to, pressed on, or put on a light emitting element for use having a light emitting layer emitting light. The film or the plate-like member has one or more optical functional films of the present invention provided in the light path along which the light output from the light emitting layer travels before exiting the element. The film or the plate-like member can be retrofitted to any existing light emitting element (for example, elements, such as a fluorescent lamp, a CRT, a PDP, and EL, having a configuration for outputting light). Note that the difference between “film” and “plate-like member” in the present specification depends on differences in flexibility or thickness, but does not intend to clearly differentiate between “film” and “plate-like member”.

FIG. 6 shows configuration examples for application in a retrofitting manner, for example, by sticking to any existing light emitting element. In the configuration examples of FIG. 6A through FIG. 6C, a cohesion material (adhesion material) layer (9) is provided on one surface of the refractive index composite structure layer (5). In the configuration example of FIG. 6A, a second cohesion material (adhesion material) layer (8) is further provided on the other surface of the refractive index composite structure layer (5). The configuration examples of FIG. 6A through FIG. 6C are available in such a state that, a film having detachability, for example, is adhered to the cohesion material (adhesion material) layer (9) in order to protect the cohesion material (adhesion material) layer (9) before the adhesion to a targeted element. The second cohesion material (adhesion material) layer (8) has the function of preventing the refractive index composite structure layer (5) from detaching from a base material (11). Typically, the adhesion strength of the second cohesion material (adhesion material) layer (8) is stronger than the adhesion strength of the cohesion material (adhesion material) layer (9).

The cohesion material (adhesion material) layer (9) and the second cohesion material (adhesion material) layer (8) contain a photo-curing-type or heat-curing-type adhesive agent (such as acrylic resin or epoxy resin) or a cohesive agent, and have cohesiveness (adhesiveness). It is preferable to use an adhesive agent or a cohesive agent which does not exercise influences such as impregnation, swelling, expansion, or warping on, for example, a surface member, the refractive index composite structure layer (5), or the base material (11) of the targeted element.

The configuration example of FIG. 6B has the refractive index composite structure layer (5) directly formed on the base material (11), but does not have the second cohesion material (adhesion material) layer (8) provided between the base material (11) and the refractive index composite structure layer (5). The configuration example of FIG. 6C is realized in a case where the refractive index composite structure layer (5) has a sufficient strength, and thus the base material (11) is not provided.

The configuration example of FIG. 6A can be formed by applying an adhesive agent or a cohesive agent on the base material (11) to form the cohesion material (adhesion material) layer (8) followed by forming the refractive index composite structure layer (5) according to a method explained later with respect to the preferred embodiments, and then further applying an adhesive agent or a cohesive agent to form the cohesion material (adhesion material) layer (9). The configuration example of FIG. 6B can be formed according to a method being the same as that for forming the configuration example of FIG. 6A excepting that the cohesion material (adhesion material) layer (8) is not formed.

An available form of configuration examples of FIG. 6A and FIG. 6B having a wide general-purpose is a film or a plate-like member which is to be stuck to, pressed on, or put on an existing light emitting element for use. For example, an optically transparent film formed of, for example, a polycarbonate is used as the base material (11), and the element is stuck to the targeted element by the cohesion material (adhesion material) layer (9).

Application of the film or the plate-like member of the present invention to an existing element is limited to a light emitting element whose light extraction surface is flat or a simple curved surface formed by bending a flat plate in one axial direction. If the existing light emitting element has a complex topological surface which is not flat or not the simple curved surface, contrivance is further required. For example, some of self-luminous elements, such as LEDs, have been subjected to any topological processes and shaped to improve the light extraction efficiency or to obtain a certain optical feature. Applying the film or the plate-like member as it is for improving the light extraction efficiency of an existing self-luminous element does not produce an improvement of the light extraction efficiency, but may damage optical functionality which the existing self-luminous element initially has. In this case, it is necessary to appropriately shape a mold object having the refractive index composite structure for improving the light extraction efficiency, in order that the mold object may correspond to a shape of the existing self-luminous element and reproduce the function of the self-luminous element (for example, optical functionality obtained from a lens included in the existing self-luminous element). However, the initial optical functionality is not always reproduced only by scaling up the shape of the existing self-luminous element, and thus an appropriate topological design may be required depending on the function of the existing self-luminous element.

The mold object may closely contact the existing self-luminous element topologically, or a distance in a range from about several nanometers to about tens of nanometers may be provided between the mold object and the self-luminous element. Light from the self luminous element can be guided as near-field light over such distance by the refractive index composite structure of the present invention for effectively improving the light extraction efficiency.

Explanations are given with reference to an LED. In order to extract a maximum amount of light in the front direction, a light extraction portion of the LED element generally has an external shape (profile) of a lens or a lens-like shape. For the existing element having such shape, covering the LED with a mold object having a cap-like shape is more appropriate than attaching a flat material, such as a film or a plate-like member by deformation. Incorporating the refractive index composite structure of the present invention in a cap-like mold object improves the light extraction efficiency. The mold object of the present invention may be an optical functional film itself or a multilayered body having an optical functional film and other films.

A cohesion material (adhesion material) layer may be provided between the cap-like mold object and the LED. However, as long as the optical connection is certainly established between the mold object and the LED due to, for example, the deformation of the mold object itself, the cohesion material (adhesion material) layer may not be necessary. Considering the process accuracy of the mold object, it is preferable that a cohesion material (adhesion material) layer is provided for physically fixing the LED on the mold object. As explained above, since the structure for retrofitting is the mold object, the optical functionality can be reproduced with the mold object being in combination with the LED. It is preferable to use a cohesion material (adhesion material) having small optical attenuation.

The present invention further provides a mold object whose shape is suitable to the shape of the light emitting element having a light emitting layer emitting light. The mold object has one or more optical functional films of the present invention provided in a light path along which light output from the light emitting layer travels before exiting the element. Examples of the mold object are a globe of an illumination apparatus, a blanket of an LED, equipment for extracting isotropic light from a fluorescent tube or a neon tube. Using such mold object enables application to existing various light emitting elements having a curved surface in a retrofitting manner.

FIG. 6C conceptually shows a configuration example of a mold object of the present invention. The configuration example of FIG. 6C includes the refractive index composite structure layer (5) as the mold object and the cohesion material (adhesion material) layer (9) formed on a surface of the refractive index composite structure layer (5) which is to be stuck to the existing light emitting element.

The refractive index composite structure layer (5) as the mold object can be formed by performing a molding process on a resin (such as acrylic resin or polycarbonate resin) which has a self-shape retaining characteristic and a molding processibility. For example, before the molding process of the resin, a very small refractive index composite structure specified by the present invention is formed inside the resin. An example of a method of forming the refractive index composite structure is a method of generating nano-order bubbles or a method of forming a nano-order structure. Specifically, the nano-order bubbles can be generated by a method in which an adhesive shearing stress generates very small, nanometer-order bubbles called nano cavities or a method in which gas is output from very small, nanometer-order pores. Alternatively, the nano-order structure can be formed by a method in which a macromolecular monomer or a liquid having a different refractive index and being insoluble in a medium is dispersed from the very small, nanometer-order pores, or the method in which nanometer-order particles are dispersed.

Generally, the resin material in which a resin or a liquid having a different refractive index is dispersed does not lead to a structure having an average refractive index which is sufficiently small compared to that of the air. Therefore, a process for changing one phase (the resin or the liquid differing in refractive index) to a gas phase may be required after the molding. Specifically, etching, dissolution, vaporization, sublimation or the like selectively performed on one phase can change the one phase (the resin or the liquid different in refractive index) to the gas phase.

After the molding process of the resin, an adhesive agent or a cohesive agent is further applied on a surface of the refractive index composite structure layer (5) which is to be stuck to the existing light emitting element to form the cohesion material (adhesion material) layer (9), which results in the configuration example of FIG. 6C.

The mold object of the present invention encompasses objects in which the film or the plate-like member of the present invention is stuck to, pressed on, or put on an existing mold object. Moreover, the mold object of the present invention encompasses objects in which the refractive index composite structure layer is formed on an outside surface or an inside surface of an existing mold object. For example, the mold object of the present invention encompasses a mold object formed such that an acrylic resin having good optical transparency and topological processibility is processed to be suitable to the shape of the existing light emitting element having a light emitting layer, and the refractive index composite structure layer, and the like are further formed.

Although configuration examples of FIG. 6A through FIG. 6C have one refractive index composite structure layer (5), the refractive index composite structure layer (5) may be provided in plural numbers.

FIG. 7 conceptually shows element configurations in which each element of FIG. 6 is attached to an existing light emitting element (general light emitters, for example, elements for outputting light or light source such as fluorescent lamp, CRT, PDP, and EL) (10). Specifically, FIG. 7A through FIG. 7C show the films, the plate-like members, or shaped materials of FIG. 6A through FIG. 6C stuck to the light emitting elements (10). If the cohesion material (adhesion material) layers (8) and (9) are ignored, it can be thought that the configurations of FIG. 7A through FIG. 7C are the same as those of FIG. 5, and light (7) from the light emitting element (10) can be efficiently extracted.

The present invention solves the problem of the light extraction efficiency of all elements emitting light from a higher refractive index layer. Specifically, the present invention is applicable to, for example, elements using a phenomenon of emitting light from a phase having a high refractive index (for example, a semiconductor LED and an organic or inorganic electroluminescence element), and elements in which a fluorescent material such as a fluorescent dye converts invisible energy such as an electron beam or ultraviolet light to visible light, and the visible light is extracted through a substrate holding the fluorescent material (for example, fluorescent lamp, fluorescent tube, CRT, FED, PDP, wavelength conversion type element (SHG (Second Harmonic Generation) element), and fluorescent type LED). Applying the present invention to these elements makes it possible to improve the luminance without influencing on the feature of the light emitting portion.

Other features, elements, steps, characteristics and advantages of the present invention will become more apparent from the following detailed description of preferred embodiments of the present invention with reference to the attached drawings.

### BRIEF DESCRIPTION OF DRAWINGS

FIG. 1 is a graph illustrating the relationship between the distance from an interface and the energy (strength) of light, where the energy (strength) of the light on the interface is 1.

FIG. 2 shows configuration examples in devices in which external excitation light excites fluorescent emission.

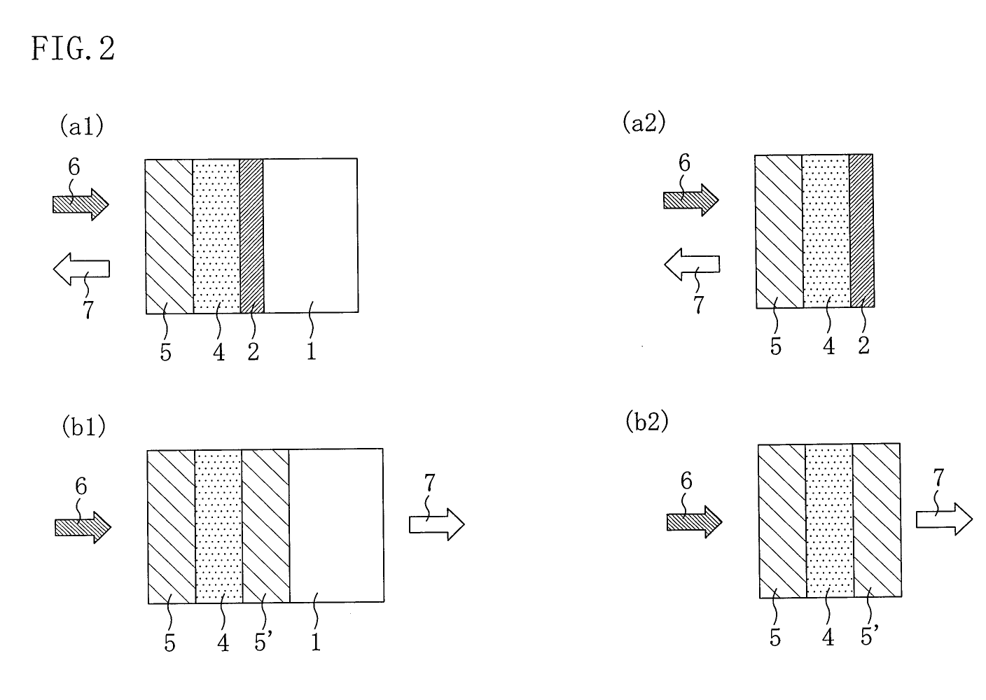

FIG. 3 shows configuration examples in devices in which external excitation energy excites fluorescent emission.

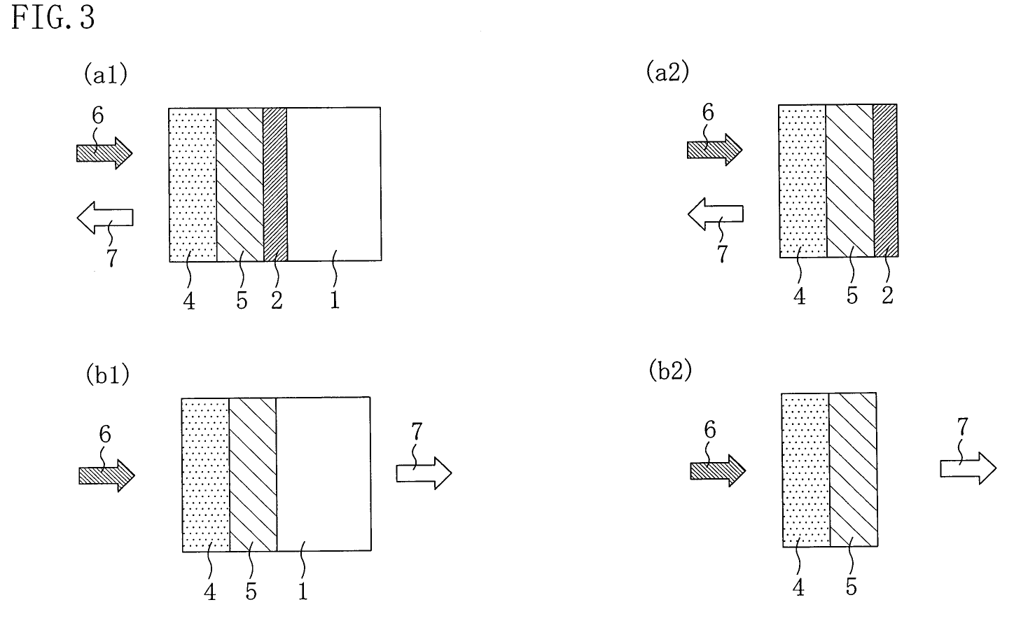

FIG. 4 shows configuration examples in devices in which a self-luminous type element adopting the method of directly extracting light is incorporated.

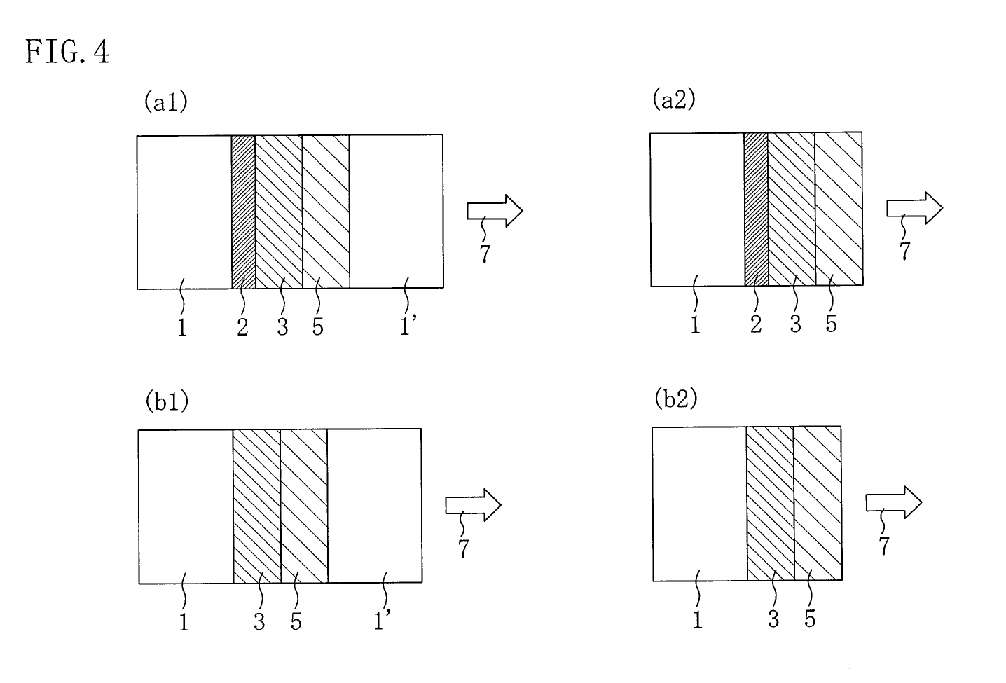

FIG. 5 shows configuration examples in devices in which light output from the self-luminous type element is used as excitation light whose wavelength is converted by, for example, a fluorescent dye, and the converted light is used for displaying.

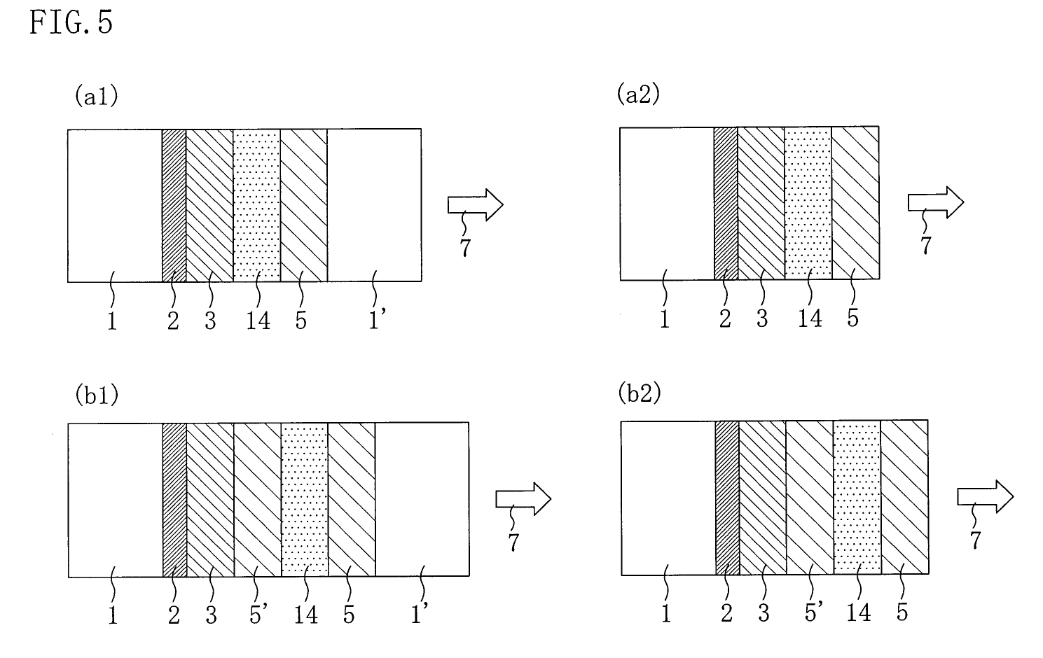

FIG. 6 shows configuration examples which are, for example, stuck to any existing light emitting element in retrofitting manner by for application.

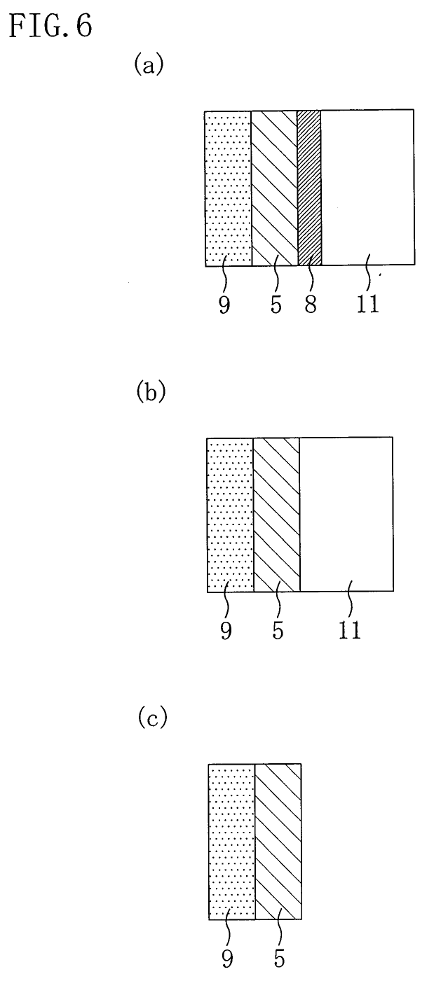

FIG. 7 shows element configurations in which each element of FIG. 6 is attached to an existing light emitting element (10).

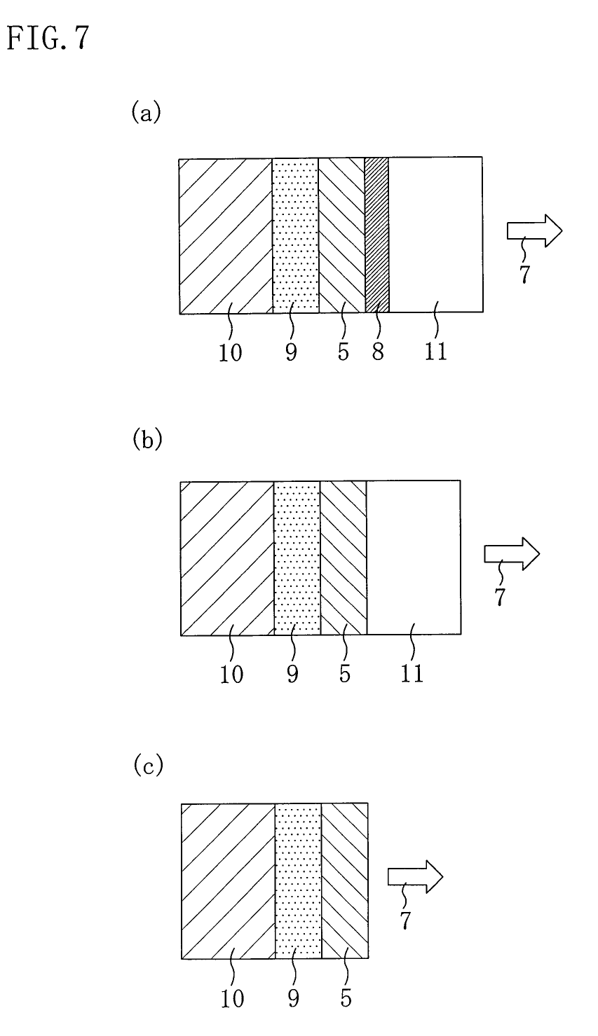

FIG. 8 schematically shows a basic configuration of a general light emitting element.

FIG. 9 schematically shows basic configurations of light emitting elements of the first preferred embodiment.

FIG. 10 schematically shows configurations of actual light emitting elements.

FIG. 11 schematically shows an element cross sectional configuration of a general fluorescent tube.

FIG. 12 schematically shows element cross sectional configurations of fluorescent tubes of the second preferred embodiment.

FIG. 13 schematically shows an element cross sectional configuration of a general LED.

FIG. 14 schematically shows element cross sectional configurations of LEDs of the third preferred embodiment.

FIG. 15 schematically shows cross sectional configurations of organic EL elements of the fourth preferred embodiment.

FIG. 16 schematically shows cross sectional configurations of PDP elements of the fifth preferred embodiment.

FIG. 17 schematically shows device configurations of Examples 1 through 8 and Comparative Example 1.

FIG. 18 shows a configuration used for measuring the amount of extracted light.

FIG. 19 is a view with which an application method used in Examples 2, 6, and 9 is explained.

FIG. 20 shows an example and a comparative example of a bottom emission type organic EL element.

### DETAILED DESCRIPTION OF PREFERRED EMBODIMENTS

Although preferred embodiments of the present invention will be described below with reference to the drawings, the present invention is not limited to the preferred embodiments below.

### First Preferred Embodiment

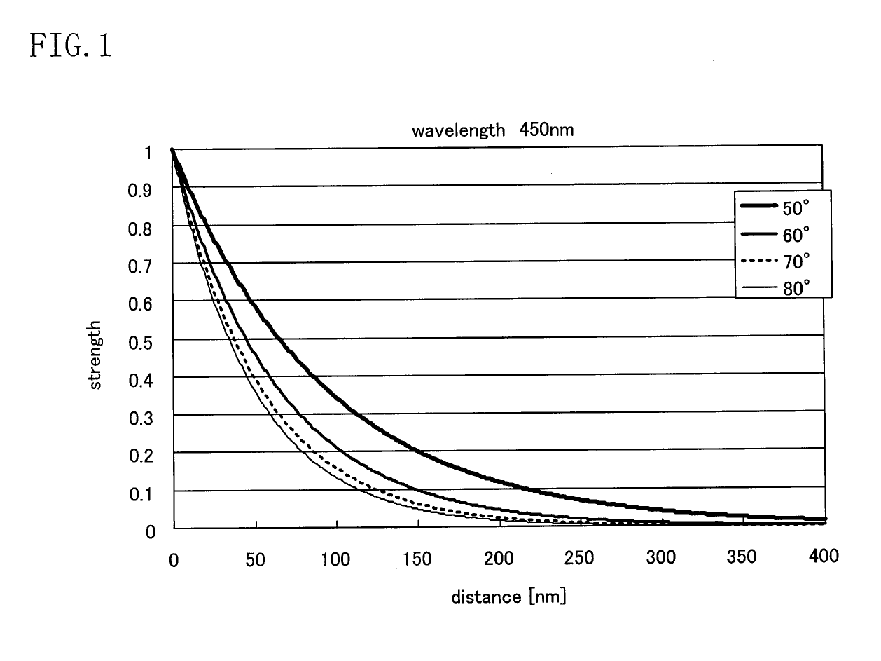

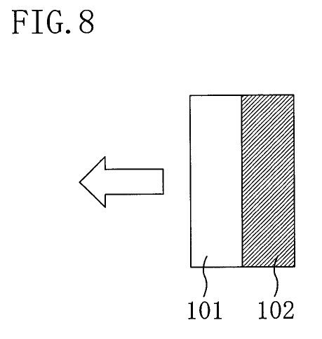

FIG. 8 schematically shows a basic configuration of a general light emitting element. The light emitting element includes a light emitting layer (102) and a substrate (101) supporting the light emitting layer (102). An arrow in FIG. 8 indicates a direction in which light is extracted from the element. The light emitting element of FIG. 1 has a bottom emission type configuration where light is extracted from a substrate (101) side. In addition to the light emitting layer (102) and the substrate (101), a light emitting element, which is an actual device may have other layers which do not contribute to light emission. However, the layers which do not contribute to the light emission can be optically identified with the substrate (101), and thus the simplified illustration as in FIG. 8 is possible.

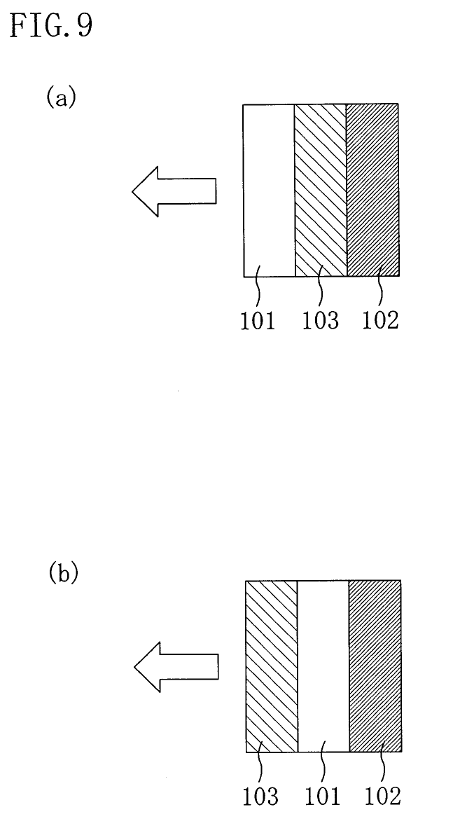

FIG. 9 schematically shows basic configurations of light emitting elements of the present preferred embodiment. In comparison with the light emitting element of FIG. 8, FIG. 9 shows where a refractive index composite structure layer is provided. The light emitting element of FIG. 9A includes the light emitting layer (102), the substrate (101) supporting the light emitting layer (102), and a refractive index composite structure layer (103) provided between the light emitting layer (102) and the substrate (101). The refractive index composite structure layer (103) includes a refractive index composite structure on a light emitting layer (102) side, and the refractive index composite structure is smaller than or equal to the light wavelength (for example, the refractive index composite structure has a size greater than or equal to 1 nm and smaller than or equal to 100 nm). The average refractive index of the refractive index composite structure layer (103) is smaller than or equal to the refractive index of the light emitting layer (102). The average refractive index of the refractive index composite structure layer (103) is, for example, within a range of 1.0 to 1.3. Note that the average refractive index of the refractive index composite structure layer (103) depends on proportion of the total volume of a high refractive index phase component forming a porous body and the total volume of a low refractive index phase. The average refractive index of the refractive index composite structure layer (103) is approximately calculated by the following expression: [average refractive index nAVR]=Σ[proportion of the volume of a phase having a refractive index ni]×[refractive index ni].

The refractive index composite structure layer (103) has a layer thickness greater than or equal to the size of the refractive index composite structure. The refractive index composite structure layer (103) has, for example, a layer thickness greater than or equal to 50 nm and smaller than or equal to 500 nm. When, in addition to extracting light in an evanescent region, the extracted light is scattered for further averaging of the profile of light which is to be output, the layer thickness of the refractive index composite structure layer (103) is set to be greater than or equal to 500 nm and smaller than or equal to several micro meters for example.

The refractive index of the light emitting layer (102) is higher than or equal to the average refractive index of the refractive index composite structure layer (103). For example, in case of π-electron system conjugated type organic material used for organic EL, the light emitting layer (102) has a refractive index of between 1.6 and 1.8. In case of a fluorescent dye or an n-channel material or a p-channel material used for a semiconductor material, the light emitting layer (102) has a refractive index of higher than or equal to 1.5. Therefore, incident light at an angle greater than the critical angle on an interface to the light refractive index composite structure layer (103) adjacent to the light emitting layer (102) conventionally experiences total internal reflection and can not be extracted. However, in the light emitting element of the present preferred embodiment, the refractive index composite structure layer (103) includes the refractive index composite structure on the light emitting layer (102) side. The refractive index composite structure has a size smaller than or equal to the light wavelength (the refractive index composite structure has a size greater than or equal to 1 nm and smaller than or equal to 100 nm). Therefore, the energy of the light which otherwise would experience total internal reflection can be extracted as evanescent light.

In the light emitting element of FIG. 9A, the refractive index composite structure layer (103) borders on the light emitting layer (102), and thus light from the light emitting layer (102) can be most efficiently extracted. Note that the refractive index composite structure layer (103) may be formed on a surface of the substrate (101) from which light is extracted as shown in FIG. 9B. Generally, a material used for a transparent substrate has the refractive index substantially equal to the refractive index of the light emitting layer (102). For example, a resin material has a refractive index higher than or equal to 1.3 and lower than or equal to 1.7, and a glass has a refractive index than or equal to 1.5 and lower than or equal to 1.8. Therefore, most of the light from the light emitting layer (102) does not experience total internal reflection on an interface between the light emitting layer (102) and the substrate (101) and penetrates through the substrate (101). Meanwhile, the air has a refractive index of about 1, and thus part of the light experiences total internal reflection on an interface between the substrate (101) and the air in the light emitting element of FIG. 9A. Compared to this, in the light emitting element of FIG. 9B, the refractive index composite structure layer (103) is formed on the surface of the substrate (101) from which the light is extracted, and thus it is possible to extract the evanescent light produced near an interface between the refractive index composite structure (103) and the substrate (101).

In FIG. 9, between the refractive index composite structure layer (103) and the light emitting layer (102), there is no layer having a refractive index lower than or equal to the refractive index of the refractive index composite structure layer (103). However, a lower refractive index layer having a refractive index lower than or equal to the refractive index of the refractive index composite structure layer (103) may be provided between the refractive index composite structure layer (103) and the light emitting layer (102). In this case, it is preferable that the lower refractive index layer has a layer thickness of smaller than or equal to 100 nm.

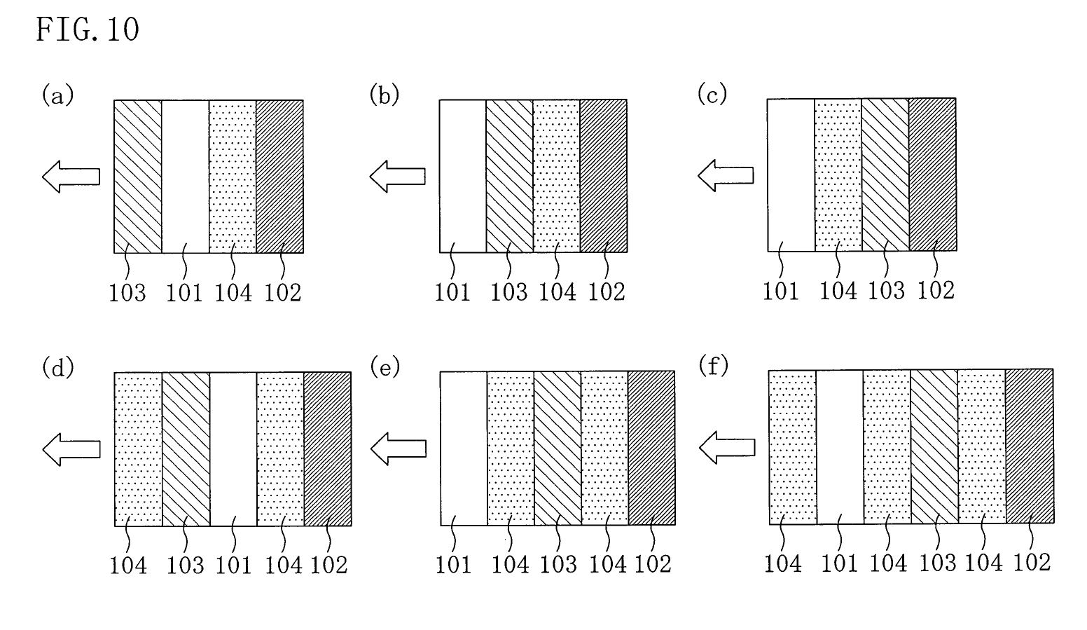

FIG. 10A through FIG. 10F are views schematically illustrating configurations of actual light emitting elements. In addition to the substrate (101), the light emitting layer (102), and the refractive index composite structure layer (103), each of the light emitting elements of FIG. 10A through FIG. 10F has at least one functional layer (104) having any function. The functional layer (104) is, for example, an inorganic protection layer or an insulation layer formed of SiO2 or SiNx; a transparent electrode layer for applying a current to the light emitting layer (102) (for example, ITO (Indium Tin Oxide) or IZO (Indium Zinc Oxide)); a p-channel/n-channel type semiconductor layer or an organic conductive material layer for moving holes and electrons toward the light emitting layer (102); an adhesion layer for forming a layered configuration by sticking layers to each other; or a polarization layer for polarizing outside light.

### Second Preferred Embodiment

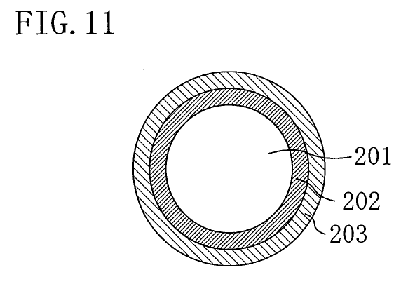

FIG. 11 is a view schematically illustrating an element cross sectional configuration of a general fluorescent tube. The fluorescent tube includes a glass tube (203) defining an outer contour of the fluorescent tube, a fluorescent material (202) provided on an inside surface of the glass tube (203), and a mercury vapor (201) encapsulated in the glass tube (203). Electrons are discharged in an atmosphere including the mercury vapor (201), which produces ultraviolet light to which the fluorescent material (202) is exposed. As a result, the fluorescent material (202) emits visible light. However, the refractive index of the fluorescent material (202) is generally higher than that of the glass tube (203), and the light from the fluorescent material (202) is emitted in all directions. Therefore, in the general fluorescent tube of FIG. 11, a component of light exists which experiences total internal reflection on an interface between the fluorescent material (202) and the glass tube (203) and thus can not enter into the glass tube (203) (hereinafter referred to also as component 1). Moreover, the refractive index of the glass tube (203) and the refractive index of air do not match to each other. Therefore, also when light entered into the glass tube (203) is output to the air, a component of light exists which experiences total internal reflection and thus can not be extracted (hereinafter referred to as component 2).

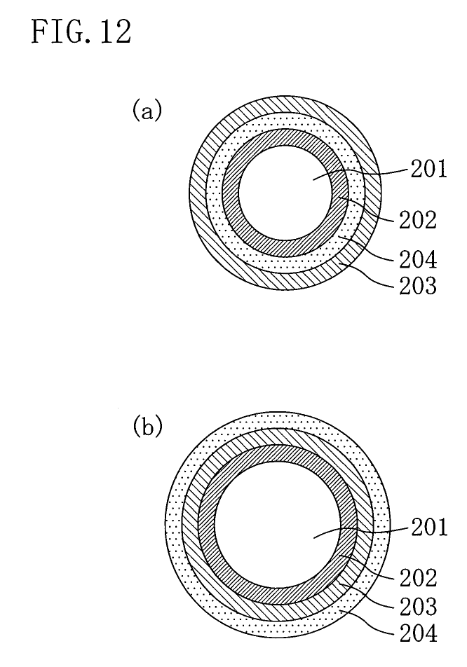

FIG. 12 schematically shows element cross sectional configurations of fluorescent tubes of the present invention. The fluorescent tube of FIG. 12A is provided with a refractive index composite structure layer (204) between the glass tube (203) defining the outer contour of the fluorescent tube and the fluorescent material (202), and thus the light of component 1 can be guided into the glass tube (203). Specific descriptions will be given below.

When the light emitted from the fluorescent material (202) impinges on the refractive index composite structure layer (204) having a refractive index lower than the refractive index of the fluorescent material (202) (the refractive index composite structure layer (204) having a refractive index close to 1), the light of component 1 exists which experiences total internal reflection according to Snell's Law. However, the light which experiences total internal reflection still has about several tens of percent of initial light energy in an area (generally called near-field region or evanescent region) within such a distance from an interface between the fluorescent material (202) and the refractive index composite structure layer (204) that is shorter than or equal to the wavelength of the incident light (see FIG. 1 for detail). The refractive index composite structure layer (204) includes a refractive index composite structure whose structural unit is in an order of smaller than or equal to the wavelength. The refractive index composite structure has interfaces between phases differing in refractive index. Light (evanescent light) which penetrates through an interface between the fluorescent material (202) and the refractive index composite structure layer (204) and enters into the refractive index composite structure layer (204) is refracted while penetrating through the interfaces between the phases in the refractive index composite structure. Therefore, the light can be guided to a direction different from the direction of an incidence on the interfaces.

As a result, the light guided to the direction different from the direction of the incidence does not go through the interface between the fluorescent material (202) and the refractive index composite structure layer (204) back into the fluorescent material (202) but can penetrate through the refractive index composite structure layer (204). This effect makes it possible for the light of component 1 which otherwise would experience total internal reflection and would not go out of the fluorescent material (202) to enter into the refractive index composite structure (204) with the light penetrating through the interface between the fluorescent material (202) and the refractive index composite structure layer (204).

The refractive index composite structure layer (204) includes a number of interfaces between the phases differing in refractive index inside the refractive index composite structure layer (204), and thus the refractive index composite structure layer (204) itself may have a light scattering characteristic. Light scattered in the refractive index composite structure layer (204) is initially the light emitted from the fluorescent material (202). However, since the refractive index composite structure layer (204) has an average refractive index close to 1, the scattered light impinging on the glass tube (203) can be identified with light output from the refractive index composite structure layer (204). The average refractive index of the refractive index composite structure layer (204) is set to be lower than the refractive index of the glass tube (203). Therefore, there is no condition under which the light output from the refractive index composite structure layer (204) experiences total internal reflection on an interface between the glass tube (203) and the refractive index composite structure layer (204). As a result, almost all the light emitted from the fluorescent material (202) is allowed to enter into the glass tube (203).

Since there is no critical angle for light incident on the higher refractive index layer (203) from the lower refractive index layer (204), the light of all incidence angle components incident from the lower refractive index layer (204) can enter into the higher refractive index layer (203).

Meanwhile, when light penetrates through the lower refractive index layer (204) and the higher refractive index layer (203) and is output to an air space having a refractive index of 1, the critical angle of the light output from the higher refractive index layer (203) to the air space is the same as the critical angle of light output from the lower refractive index layer (204) directly to the air space. Therefore, when the light entered into the higher refractive index layer (203) from the lower refractive index layer (204) is output from the higher refractive index layer (203) to the air space, it is possible to output only the light of incidence angle component which does not exceed the critical angle of light when output from the lower refractive index layer (204) to the air space. Therefore, although the higher refractive index layer (203) is provided, the light of incidence angle components which can be output to the air space is the same as the light which can be output (extracted) from the lower index refractive index layer (204) to the air space.

To be exact, even if light has an incidence angle smaller than or equal to the critical angle, the light of all incidence angle components includes light of component which are reflected between two layers differing in refractive index, and thus an incidence of 100% of light can not be realized. However, the injection efficiency of light incident from one layer to another layer is more strongly influenced by the critical angle than by the injection ratio on an interface between the two layers. The injection ratio depends on difference in refractive index between the two layers. The critical angle is a condition determining whether light having a certain incidence angle can enter into the adjacent layer or experiences total internal reflection.

Therefore, compared to a case where the lower refractive index layer (204) is not provided, a component which is attenuated due to the existence of the higher refractive index layer (203) is reduced into three components: a surface reflection component on an interface through which light enters from the lower refractive index layer (204) into the higher refractive index layer (203); a surface reflection component at the moment when light is output from the higher refractive index layer (203) to the air space; and a component which is attenuated while light penetrates through the higher refractive index layer (203).

The average refractive index of the refractive index composite structure layer of the present invention is typically lower than or equal to 1.4, and can be ideally reduced to lower than or equal to 1.1. That is, extracting light from the lower refractive index layer (204) becomes possible, the layer (204) having a refractive index lower than the refractive index of the conventional light emitting layer, which is greater than or equal to 1.5. Therefore, extracting such light becomes possible that could not be extracted due to an incidence angel greater than the critical angle and total internal reflection inside the element, so that significantly more light compared to the conventional element configuration can be extracted.

In the fluorescent tube of FIG. 12B, the refractive index composite structure layer (204) is not provided between the glass tube (203) and the fluorescent material (202), and thus the light of component 1 can not be guided into the glass tube (203). However, in the fluorescent tube of FIG. 12B, the refractive index composite structure layer (204) is formed on an outer surface of the glass tube (203), and thus the light of component 2 can be output from the glass tube (203). Specific descriptions will be given below.

The average refractive index of the refractive index composite structure layer (204) is lower than the refractive index of the glass tube (203). Therefore, part of the light incident on the refractive index composite structure layer (204) from the glass tube (203) experiences total internal reflection on the interface between the glass tube (203) and the refractive index composite structure layer (204). However, the refractive index composite structure layer (204) includes a refractive index composite structure within a region in which light of total internal reflection component enters as energy (evanescent region). The structural unit of the refractive index composite structure is in an order of smaller than or equal to the wavelength, and the refractive index composite structure is provided near the interface between the glass tube and the refractive index composite structure layer. The refractive index composite structure includes interfaces between phases differing in refractive index. The light of total internal reflection component is guided to a direction of azimuth angle differing from an azimuth angle of incident light on the interfaces. Therefore, light experiencing total internal reflection reduces, and thus light which can enter into the refractive index composite structure layer (204) increases. Therefore, the light output from the refractive index composite structure layer (204) to the air can be identified with light produced in the refractive index composite structure layer (204).

Moreover, the light entered into the refractive index composite structure layer (204) experiences a complex reflection/refraction by a number of interfaces existing in the refractive index composite structure layer (204) and is output from the refractive index composite structure layer (204) as scattered light. Moreover, since the average refractive index of the refractive index composite structure layer (204) approximates to the refractive index of the air, less components of light experience total internal reflection on the interface between the refractive index composite structure layer (204) and the air (that is, on an outer surface of the refractive index composite structure layer (204)). As a result, the component 2, which is loss of light is reduced, and the amount of extracted light increases.

In the present preferred embodiment, the descriptions have been given with reference to the fluorescent tube to which the present invention is applied. However, the present invention is applicable to a CRT or an FED in which an electron beam is used as energy for exciting a fluorescent dye for light emission instead of ultraviolet light. Also in the CRT or the FED, since visible light is basically emitted from the fluorescent dye, a light extraction improving effect can be obtained as in the fluorescent tube of the present preferred embodiment.

### Third Preferred Embodiment

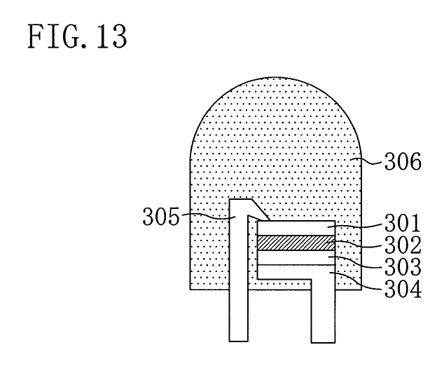

FIG. 13 is a view schematically illustrating an element cross sectional configuration of a general LED. The LED includes an anode (305) and a cathode (304) which are electrodes, an n-channel layer (301) for transporting electrons toward the anode (305), a p-channel layer (303) for transporting holes toward the cathode (304), a light emitting layer (302) between the channel layers (301) and (303), and a mold resin layer (306) encapsulating the element overall. In an actual LED, a joint interface of the n-channel layer and the p-channel layer may serve as a light emitting layer, and thus a light emitting layer of different composition may not be provided.

In the LED, light emitted from the light emitting layer (302) of a semiconductor is guided through the n-channel (301) or p-channel layer (303) and the electrode layer (304) provided in a light extraction direction and arrives at the mold resin layer (306). In this case, every layer constituting the LED is formed by injecting a very small amount of dopant into a semiconductor compound (for example, Si, Ge, Ga) which is a base material for the element, and thus there is no great difference in refractive index between the individual layers. Specifically, layers formed of a general material have a refractive index of greater than or equal to 1.8. Therefore, great loss of light is not caused by penetration through these layers.

However, the resin layer (306) adjacent to the semiconductor layer emitting light is generally formed by, for example, an epoxy or acrylic resin having a refractive index of about 1.5 which is different from the refractive index of the semiconductor layer by 0.3 or more. Therefore, in the general LED of FIG. 13, light output from a layer having a refractive index of greater than or equal to 1.8 (typically a refractive index of about 2) to a layer having a refractive index of about 1.5 includes a component of light which can not enter into the layer having a refractive index of about 1.5 due to the total internal reflection on an interface (hereinafter referred to as component 3). In other words, in the general LED of FIG. 13, an occurrence of loss of light on the interface between the semiconductor layer and the mold resin layer can not be avoided.

The mold resin layer (306) has a refractive index of about 1.5. Compared to this, the refractive index of air is about 1. Therefore, light output from the layer having a refractive index of 1.5 to the layer having the refractive index of about 1 includes a component of light which experiences total internal reflection on an interface and can not enter into the layer having a refractive index of about 1 (hereinafter referred to as component 4). In other words, in the general LED of FIG. 13, an occurrence of loss of light on the interface between the mold resin layer and the air can not be avoided when the final light extraction is performed.

Conventionally, various propositions have been made for improving the light extraction efficiency of an LED and applied to actual devices. Most typically, a configuration is adopted in which the element has an output side formed in a shape of a lens, and such element is available in the market. However, light is basically emitted from the entire surface of the semiconductor device. Therefore, although the extraction efficiency is improved by the lens, the improvement of the extraction efficiency is limited.

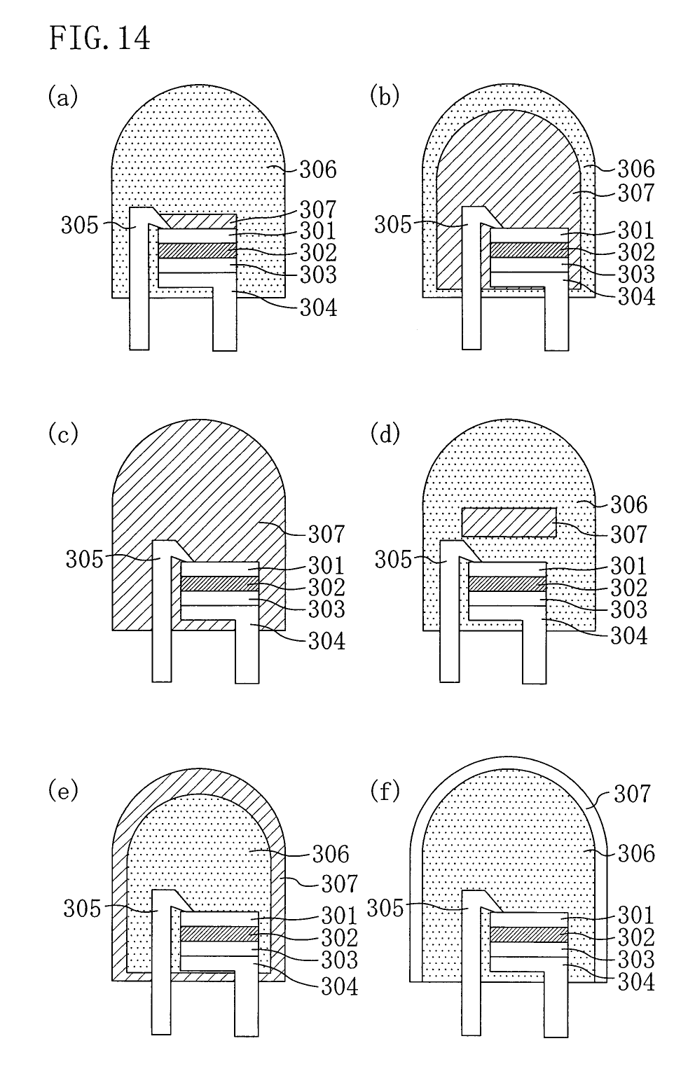

FIG. 14 schematically illustrates element cross sectional configurations of LEDs of the present preferred embodiment. The LED of FIG. 14A has a refractive index composite structure layer (307) formed on an output surface. In the LED of FIG. 14B, the refractive index composite structure layer (307) covers the element overall, and the element is encapsulated in the mold resin layer (306). Alternatively, as shown in FIG. 14C, instead of the mold resin (306), the refractive index composite structure layer (307) may encapsulate the element overall. Alternatively, the refractive index composite structure layer (307) may be formed in a light path of output light as shown in FIG. 14D, or the refractive index composite structure layer (307) may cover the mold resin layer (306) as shown in FIG. 14E. However, the light extraction efficiency of the LEDs of FIG. 14D and FIG. 14E is not as good as that of the LEDs of FIG. 14A through FIG. 14C. Alternatively, as shown in FIG. 14F, the refractive index composite structure layer (307) may be a blanket, which is a mold object, and the blanket may cover the mold resin layer (306).

The LEDs of FIG. 14A through FIG. 14C differ in proportion of the refractive index composite structure layer (307) in the whole element, but are common in that as a basic configuration, the refractive index composite structure layer (307) is adjacent to the light emitting semiconductor layer. In the LEDs of FIG. 14A and FIG. 14B, light penetrates through the refractive index composite structure layer (307) and the mold resin layer (306) and then is output to the air. In this case, the light penetration efficiency on an interface between the refractive index composite structure layer (307) and the mold resin layer (306) may differ from that on an interface between the mold resin layer (306) and the air. However, in the LEDs of FIG. 14A and FIG. 14B, it is possible to extract the light of the component 3, and thus the effect of improving the light extraction efficiency can be obtained. Moreover, the LEDs of FIG. 14A and FIG. 14B are thought to be effective as a configuration with which the mechanical strength of the refractive index structure layer (307) is supplemented.

Compared to this, the LED of FIG. 14C has the refractive index composite structure layer (307) adjacent to the air, the refractive index composite structure layer having an average refractive index which approximates to the refractive index of the air. Therefore, it is possible to extract the light of component 4 as well as of component 3, so that the effect of further improving the light extraction efficiency can be obtained.

In actual device configurations, the mold resin layer (306) may be provided between the refractive index composite structure layer (307) and the semiconductor layer as shown in FIG. 14D through FIG. 14F. In the LED of FIG. 13, when light is output from the mold resin layer (306) having a refractive index of about 1.5 to the air space having a refractive index of about 1, the light of component 4 exists which has an incidence angle exceeding the critical angle and thus can not enter into the air space.

In the LED of FIG. 14D, light emitted from the semiconductor layer penetrates through the mold resin layer (306) and then impinges on the refractive index composite structure layer (307) having an average refractive index approximating to the refractive index of the air. Since the refractive index composite structure layer (307) includes the refractive index composite structure, the light including the light of component 4 from the mold resin layer (306) having a refractive index of about 1.5 can enter into the refractive index composite structure layer (307). The component 4 has an incidence angle which exceeds the critical angle and thus conventionally can not enter into the refractive index composite structure layer (307). Moreover, the light entered into the refractive index composite structure layer penetrates through the plurality of interfaces, and in the course of this, the light is converted to light having a characteristic similar to a light scattering characteristic. In other words, light from the layer (306) having a refractive index of about 1.5 can be converted to light which is apparently the same as light emitted from the refractive index composite structure layer (307). Therefore, the LED of FIG. 14D can not avoid three influences; loss on an interface through which light emitted from the semiconductor layer enters into the mold resin layer (306), loss when the light is output from the mold resin layer (306) to the air, and the attenuation when the light penetrates through the mold resin layer (306). However, the LED of FIG. 14D can reduce the loss of component 4 whose incidence angle on the interface between the mold resin layer (306) and the refractive index composite structure layer (307) exceeds the refractive index. Note that in an actual element, as factors reducing the amount of extracted light, the loss of component 4 having an incidence angle exceeding the critical angle is greater than the loss on the interfaces. Therefore, even when the refractive index composite structure layer (307) is not adjacent to the air space as shown in FIG. 14D, the effect of the present invention can be obtained.

In the LED of FIG. 14E, the refractive index composite structure layer (307) is adjacent to the air space, the refractive index composite structure layer (307) having an average refractive index which approximates to the refractive index of the air. Therefore, in addition to the effect obtained by the LED of FIG. 14D, there is an advantage that that the light extraction efficiency is improved when the light is output to the air space.

In the LED of FIG. 14F, it is possible to adopt a mold object (blanket), which is the refractive index composite structure layer (307) in a retrofitting manner. Therefore, in addition to the effect obtained by the LED of FIG. 14E, there is an advantage that the configuration of FIG. 14F can improve the light extraction efficiency of the existing LED of FIG. 13.

The effects obtained by the LEDs of FIG. 14D through FIG. 14F are limited to extracting the light of component 4. Therefore, with regard to improvement of the light extraction efficiency, the LEDs of FIG. 14D through FIG. 14F are not necessarily as good as the LEDs of FIG. 14A through FIG. 14C.

However, as to loss which occurs when light is extracted from the element, loss which occurs when light from the light emitting layer enters into the mold resin layer (306) is substantially the same as loss which occurs when light from the mold resin layer (306) enters into the air space. Specifically, both loss which occurs when light is output from a layer having a refractive index of about 2 to a layer having a refractive index of about 1.5 and loss which occurs when light is output from the layer having a refractive index of about 1.5 to a layer having a refractive index of about 1 are about 30% of the emitted light. In other words, the effect obtained by extracting the light of component 4 is substantially the same as the effect obtained by extracting the light of component 3. Therefore, a sufficient effect can be obtained only by enabling the light extraction of component 4 compared to other methods for improving the light extraction efficiency. Therefore, the LEDs of FIG. 14D through FIG. 14F are effective.

### Fourth Preferred Embodiment

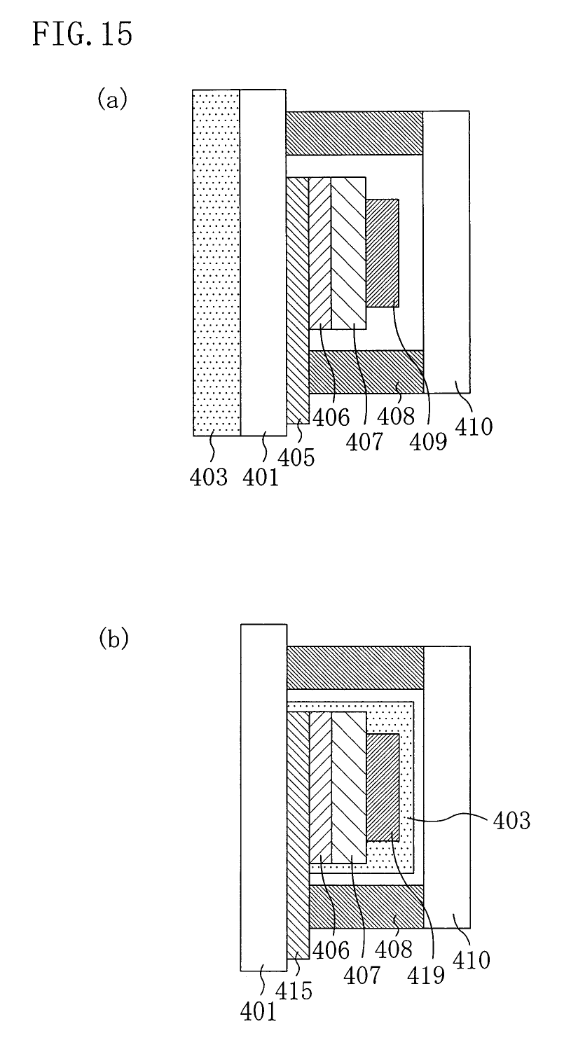

FIG. 15A and FIG. 15B are views schematically illustrating cross sectional configurations of organic EL elements of the present preferred embodiment. The organic EL element of FIG. 15A includes a substrate (401) for supporting the element, an anode (405) and a cathode (409) formed over the substrate (401) to drive a picture element, a hole transport layer (406) on the anode (405), and a light emitting layer (407) between the cathode (409) and the hole transport layer (406). Hereinafter, the anode (405), the hole transport layer (406), the light emitting layer (407), and the cathode (409) are collectively referred to also as “light emitting element section”. Note that a device configuration may be possible which has a further layer, such as a hole injection layer, between the hole transport layer (406) and the light emitting layer (407).

The organic EL element of FIG. 15A includes seal materials (408) and a seal substrate (410) for encapsulating the light emitting element section. Generally, a space encapsulated by the seal materials (408) and the seal substrate (410) is filled with an inert material such as inert gas or oil.

The organic EL element of FIG. 15A is bottom emission type in which light is extracted from a substrate side. The anode (405) is formed of a transparent electrode material such as ITO. The cathode (409) is formed of a reflective electrode material such as aluminum. The organic EL element of FIG. 15A includes a refractive index composite structure layer (403) on an outer surface of the substrate (401). Since the refractive index of the substrate (401) is higher than the average refractive index of the refractive index composite structure layer (403), part of light incident on an interface between the substrate (401) and the refractive index composite structure layer (403) experiences total internal reflection. However, since the refractive index composite structure layer (403) includes a refractive index composite structure having a size smaller than or equal to the light wavelength (for example, the refractive index composite structure is greater than or equal to 1 nm and smaller than or equal to 100 nm), energy of the light which would otherwise experience total internal reflection can be extracted as evanescent light. Moreover, since the average refractive index of the refractive index composite structure layer (403) approximates to the refractive index of the air, less components of light experience total internal reflection on an interface between the refractive index composite structure layer (403) and the air (that is, on an outer surface of the refractive index composite structure layer (403)). Therefore, the loss of light is reduced, and the amount of extracted light increases.

A further refractive index composite structure layer may be provided between the anode (405) and the substrate (401). This can reduce components of light which experience total internal reflection due to the difference in refractive index between the anode (405) and the substrate (401) and further increase the amount of extracted light.

The organic EL element of FIG. 15B is different from the organic EL element of FIG. 15A in that the organic EL element of FIG. 15B is a top emission type in which light is extracted from a side opposite to the substrate, an anode (415) is formed of a reflective electrode material such as aluminum, and a cathode (419) is formed of a transparent electrode material such as ITO. Moreover, the organic EL element of FIG. 15B is different from the organic EL element of FIG. 15A also in that the refractive index composite structure layer (403) covers the light emitting element section in the encapsulated space.

In the organic EL element of FIG. 15A, since the light emitting element section and the inert material differ in refractive index, a component of light experiences total internal reflection on an interface between the light emitting element section and the inert material. Compared to this, the organic EL element of FIG. 15B includes the refractive index composite structure element (403) covering the light emitting element section in the encapsulated space, which allows an efficient guide of light emitted from the light emitting element section into the inert material.

Note that the space encapsulated by the seal materials (408) and the seal substrate (410) may be filled with the refractive index composite structure layer (403). Alternatively, a further refractive index composite structure layer may be formed on an outer surface of the seal substrate (410). This can reduce components of light which experience total internal reflection on an interface between the seal substrate (410) and the air.

The organic EL element of the present preferred embodiment is a passive matrix type display including a plurality of picture elements arranged in matrix. The picture elements are defined by the anode (405) having a stripe structure and the cathode (409) provided to cross with the anode (405) which cross with each other. Note that the element of the present invention is applicable to the active matrix type, and the anode (405) or the cathode (409) may be connected to a switching element for driving. Examples of the switching element are a three-terminal element such as a TFT (Thin Film Transistor) and a two-terminal element such as a MIM (Metal-Insulator-Metal).

In the present preferred embodiment, descriptions have been given with reference to the organic EL element. However, the present invention is also applicable to an inorganic EL element. Although the organic EL element and the inorganic EL element differ in configuration and detailed mechanism of the light emitting element section, the configuration for extracting light is not greatly different. Therefore, applying the present invention to the inorganic EL element can provide an effect equivalent to the effect obtained in the organic EL element of the present preferred embodiment.

### Fifth Preferred Embodiment

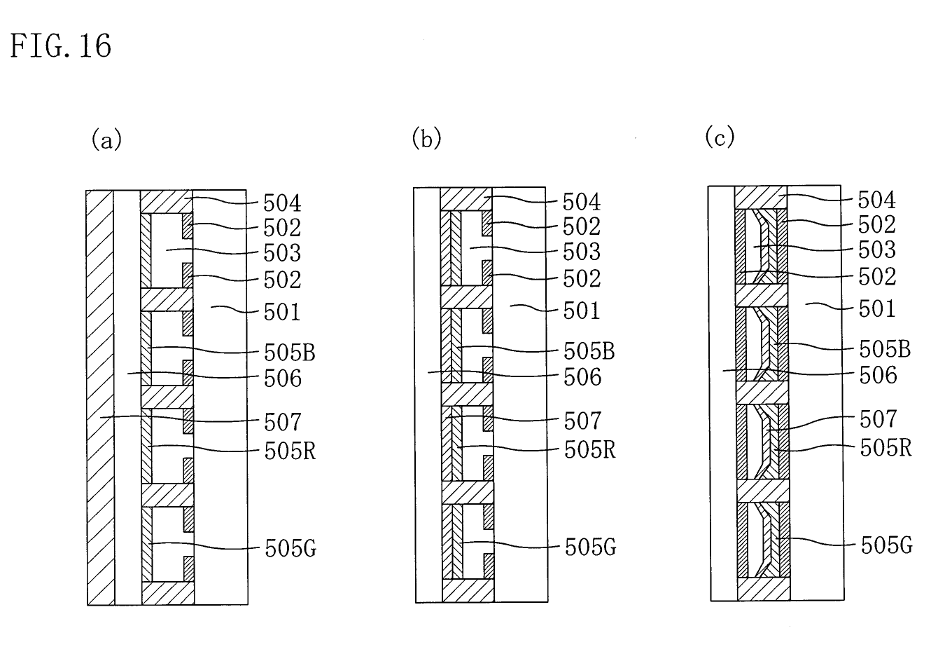

FIG. 16A, FIG. 16B, and FIG. 16C are views schematically illustrating cross sectional configurations of PDP elements of the present preferred embodiment. Each of the PDP elements of FIG. 16A, FIG. 16B, and FIG. 16C includes: a substrate (501) for supporting the element; a counter substrate (506) which is arranged opposite the substrate (501); spacer walls (so-called ribs) (504) with which a space between the two substrates (501) and (506) is divided into cells; pairs of electrodes (502) for discharging electrons in the space in the cells; spaces (503) which are filled with an inert gas for generating plasma by discharging electrons; and fluorescent material layers (505R), (505G), and (505B) of three colors, i.e., red, green, and blue.

In the PDP elements of FIG. 16A and FIG. 16B, irradiating the fluorescent material layers (505R), (505G), and (505B) for each color with ultraviolet light generated by plasma discharge generates visible light of each color, and the visible light penetrates through the counter substrate (506) to be displayed. In the PDP element of FIG. 16C, the ultraviolet light generated by the plasma discharge penetrates through refractive index composite structure layers (507), and then with the ultraviolet light, the fluorescent material layers (505R), (505G), and (505B) for each color are irradiated. As a result of irradiating the fluorescent materials with the ultraviolet light, visible light of each color is generated, and the visible light penetrates through the counter substrate (506) to be displayed. Note that a material for the substrates (501) and (506) is typically glass.

The PDP element of FIG. 16A includes a refractive index composite structure layer (507) on an outer surface of the counter substrate (506). Since the refractive index of the counter substrate (506) is higher than the average refractive index of the refractive index composite structure layer (507), part of light incident on an interface between the counter substrate (506) and the refractive index composite structure layer (507) experiences total internal reflection. However, since the refractive index composite structure layer (507) includes a refractive index composite structure having a size smaller than or equal to the light wavelength (for example, the refractive index composite structure is greater than or equal to 1 nm and smaller than or equal to 100 nm), energy of the light which would otherwise experience total internal reflection can be extracted as evanescent light. Moreover, since the average refractive index of the refractive index composite structure layer (507) approximates to the refractive index of the air, less components of light experience total internal reflection on an interface between the refractive index composite structure layer (507) and the air (that is, on an outer surface of the refractive index composite structure layer (507)). Therefore, the loss of light is reduced, and the amount of extracted light increases.

The PDP element of FIG. 16B includes the refractive index composite structure layers (507) between the counter substrate (506) and each of the fluorescent material layers (505R), (505G), and (505B). The refractive index of each of the generally used fluorescent material layers (505R), (505G), and (505B) is higher than the refractive index of glass used for the general counter substrate (506). Therefore, in the PDP element of FIG. 16B, there is a component of light which experiences total internal reflection on an interface between the counter substrate (506) and each of the fluorescent material layers (505R), (505G), and (505B). However, the PDP element of FIG. 16B includes the refractive index composite structure layers (507) between the counter substrate (506) and each of the fluorescent material layers (505R), (505G), and (505B). This makes it possible to extract the light in the evanescent region according to the present invention, so that the light emitted from the fluorescent material layers (505R), (505G), and (505B) is effectively guided into the counter substrate (506).

Moreover, the average refractive index of the refractive index composite structure layer (507) is lower than the refractive index of the counter substrate (506). Therefore, it is possible to extract an incidence angle component which is included in light incident on the counter substrate (506) from the refractive index composite structure layer (507) and which can be output to the air from the refractive index composite structure (507) via the counter substrate (506). Therefore, loss of light which occurs when the light is output from a higher refractive index layer reduces, and the amount of extracted light increases. It is preferable that a further refractive index composite layer is formed on the outer surface of the counter substrate (506) as in the PDP element of FIG. 16A.

The PDP element of FIG. 16C includes the fluorescent material layers (505R), (505B), and (505G) over the substrate (501), and further includes the refractive index composite structure layers (507) each of which is provided on a surface of each of the fluorescent material layers (505R), (505B), and (505G). In this element configuration, the ultraviolet light output from plasma generated between the electrodes (502) in pairs penetrates through each refractive index composite structure layer (507) and then arrives at the fluorescent material layer (505R), (505G), and (505B). In the course of this, transmission loss occurs. However, the refractive index composite structure layer (507) has a refractive index of a value between the refractive index 1 of the spaces (503) having a condition close to vacuum and the refractive index of each of the fluorescent material layers (505R), (505B), and (505G). Therefore, the effect of reducing the loss of incidence on the refractive index composite structure (507) is obtained. Moreover, the refractive index composite structure layer (507) itself has a thin layer thickness, and thus it is possible to ignore the transmission loss. Therefore, it can be thought that the loss of light in the UV light arriving at the fluorescent material layer (505R), (505G), and (505B) from the plasma spaces (503) is small.

The UV light arrived at the fluorescent material layers (505R), (505B), and (505G) induces light of fluorescence. The output efficiency of component of the light which can be directly output to the spaces (503) having a condition close to vacuum is equal to the output efficiency from a medium having a refractive index of 1.5 to a medium having a refractive index of 1. The reason for this is that the fluorescent material itself has a refractive index of higher than 1 (in a general fluorescent material, higher than or equal to 1.5). Therefore, according to a simple arithmetic, about 70% of the light of fluorescence can not be extracted. However, since the refractive index composite structure layer (507) is provided adjacently to each of the fluorescent material layers (505R), (505B), and (505G), the light emitted from each of the fluorescent material layers is extracted in the evanescent region, which creates a state apparently equivalent to a state where light is emitted from a layer having the average refractive index of the refractive index composite structure layer (507). In this state, the light which can be output to the vacuum layers (503) has an output efficiency of equal to the output efficiency from the layer having the average refractive index of the refractive index composite structure layer (507) to the layer having a refractive index of 1.

The light output to the vacuum layers (503) penetrates as display light through the counter substrate (506) and the electrode (502) on a surface of the counter substrate (506). While penetrating, the light impinging on interfaces between the layers suffers reflection loss and experiences penetration attenuation. However, there is no condition causing the greatest loss of light, i.e., no incidence angle greater than the critical angle, and thus the amount of extracted light increases. It is preferable that a further refractive index composite layer is formed on the outer surface of the counter substrate (506) as in the PDP element of FIG. 16A.

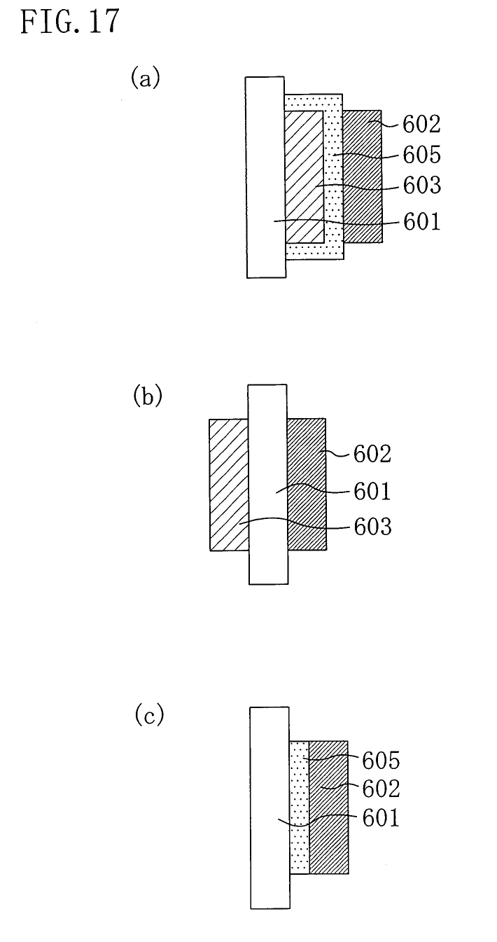

Next, for a more specific description of the light emitting element of the present invention, with reference to the drawings, examples and comparative examples for device configurations are given. FIG. 17 schematically shows device structures of Examples 1 through 8 and Comparative Example 1, wherein FIG. 17A shows a device configuration of the first through fourth preferred embodiments, FIG. 17B shows a device configuration of the fifth through eighth preferred embodiments, and FIG. 17C shows a device configuration of Comparative Example 1.

### Example 1

In 20 ml of isopropyl alcohol (IPA), 2 g of a micro particle material containing 53 nm particles (styrene resin (core)/acrylic resin (clad) type resin, Nippon Paint Co., Ltd., NC-56) was dispersed. Then, filtration of particles greater than or equal to 200 nm was performed by using a millipore filter for removing 0.2 μm water type particles.

That the micro particles are dispersed in the solution can be confirmed by the fact that collimated light (for example, a laser beam) incident on a container containing the dispersion liquid causes Tyndall phenomenon on a light path of the laser.

After the filtration, the dispersion liquid was moved in a solution tank for an airbrush. Using the airbrush, the dispersion liquid was splayed toward a glass substrate (Corning Inc., #1736, non-alkali glass) (601). Spraying was performed under such a condition that the IPA, which is a particle dispersion agent, vaporizes while the dispersion liquid in the form of mist falls toward the glass substrate (601). To realize the condition, the glass substrate (601) was put on a hot plate and the substrate temperature was increased to 150° C. or higher. The spraying of the dispersion liquid was carried out for about 50 seconds, while a sufficient space was kept for splaying so that the liquid drop sprayed from the airbrush may not fall on the glass substrate (601), with the liquid drop still containing the IPA. As a result, a structure film, which is a refractive index composite structure layer (603) was formed on the glass substrate (601).

The glass substrate (601) was cooled to ambient temperature. Then, on a surface of the substrate (601) facing the refractive index composite structure layer (603), vacuum deposition of gold of 50 nm was carried out to form a protection film (605), which is a dense, optically transparent film. Note that the protection film (605) also serves as an electrode.

Application of a toluene solution containing a light emitting material (fluorescent material 1) for organic EL was carried out by a spin coater in the atmosphere (initial rotation of 500 rpm for 5 seconds and main rotation of 1500 rpm for 15 seconds). The glass substrate (601) was baked for about 30 minutes on the hot plate having a temperature of 100° C. to form a light emitting layer (602).

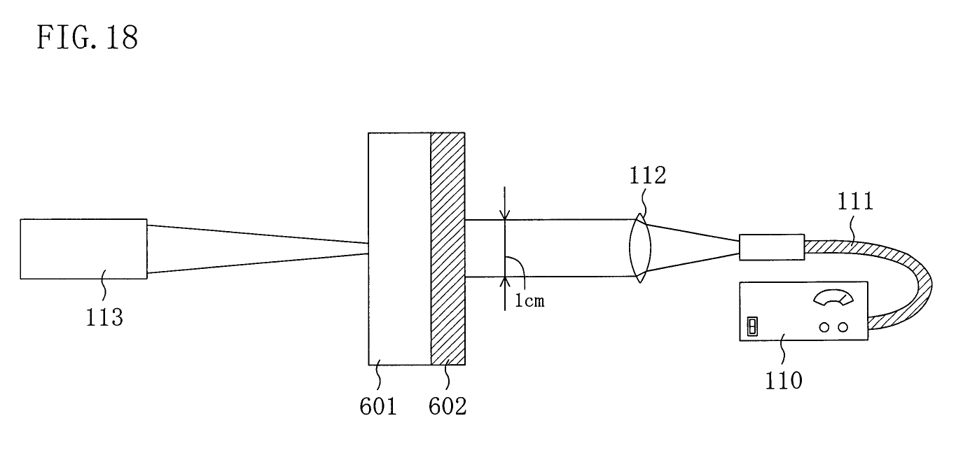

The light emitting layer (602) over the glass substrate (601) was irradiated with UV light from a UV lamp (Hamamatsu Photonics K.K., Photocure200). Then, the luminance of fluorescence generated by UV light excitation was measured at a glass substrate (601) side. FIG. 18 is a view illustrating a configuration used for measuring the amount of extracted light. The UV lamp (110) outputs UV light from a metal halide lamp light source via a fiber (111). The UV light penetrates through a lens (112) and arrives at the light emitting layer (602) on the substrate (601). The positional relationship between the fiber (111), the lens (112), and a sample was adjusted for setting the diameter of an irradiation surface to about 1 cm. For all samples (Examples 1 through 9 and Comparative Examples 1 and 2), the distance between the light source and the samples was fixed for realizing a constant current value of the light source. The light emitting layer (602) irradiated with the UV light generates fluorescence. Using a luminance meter (113) arranged on a ray axis, the luminance of the fluorescence was measured in two directions, i.e., in a normal (front) direction (on UV irradiation ray axis) and in a direction deviating by 45° from the normal (45° direction) to the substrate surface. Note that a luminance meter (LS-100) as the luminance meter (113) and a close-up lens (No. 110) of Minolta Co., Ltd. were used, and the object distance was set to 220 nm. The result of measurement is shown in Table 1.

Moreover, using an Abbe refractometer (NAR-2T·L0, Atago Co., Ltd.), the refractive index of the formed refractive index composite structure layer (603) was measured. As a measurement sample, a refractive index composite structure layer (603) was used on which the electrode (605) had not yet formed. Before the measurement, it had been confirmed that the thickness of the structure film was equal to or greater than 200 nm. Specifically, the confirmation was made such that a part of the structure film was shaved with a knife, and the height from a surface of the underlying glass to a top part of the structure film was scanned using step-height measuring apparatus P-11 (KLA-Tencor Corporation). The measurement was performed such that the refractive index composite structure layer (603) was brought into contact with a prism surface of the refractometer without using matching oil, and then a weight of 50 g was put thereon for fitting of the refractive index composite structure layer (603) on the prism surface. The result is shown under “structure refractive index” in Table 2.

Furthermore, the refractive index of the micro particle material itself was measured. Specifically, in 50 ml of toluene, 1 g of resin micro particles were dispersed and stirred for 15 hours in an open vessel at ambient temperature for dissolution. After about 5 minutes since the stirring was stopped, supernatant fluid was extracted by a glass pipette. On the glass substrate heated to a temperature of 50° C., several drops of the supernatant fluid were directly dropped and heated to remove the toluene, so that a film was formed. The refractive index of the formed film was measured by the same method as that used for the structure film. The result is shown under “structure film material refractive index” in Table 2.

### Example 2

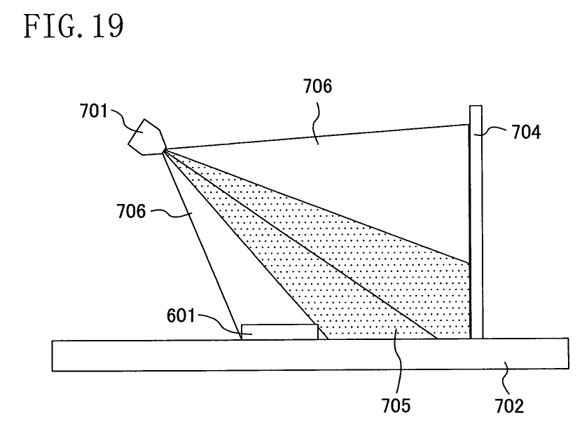

An organic EL element was produced through the same steps as those of Example 1 excepting the step of spraying the micro particle material to form the structure film. FIG. 19 is a view with which a spraying method of the present invention is described. With reference to FIG. 19, descriptions will be given of the step of spraying the micro particle material to form the structure film of the present example.

A micro particle dispersion liquid is sprayed using an airbrush (701). As shown in FIG. 19, the substrate (601) for formation of a refractive index composite structure is put on a hot plate (702) with a surface upward on which the refractive index composite structure is to be formed. The substrate (601) is put in an area (706) in which liquid in the form of mist sprayed by the airbrush (701) falls while keeping out of an area (705) in which liquid drops coming from the airbrush (701) directly fall. Since the sprayed liquid includes particles smaller than or equal to 1 μm and the particles are prone to spreading, a screen (704) is provided to prevent the liquid in the form of mist from spreading. Spraying to the screen (704) generates an air current, and using the air current, liquid drops of the solution containing micro particles output from the airbrush (701) are scattered in the form of mist. The liquid in the form of mist is once stirred up in the turbulence and then precipitated, so that more solvent (IPA) is vaporized which is used as a dispersion medium for the particles. Therefore, on a surface of the substrate (601) for forming the refractive index composite structure, the particles dispersed in the liquid can be precipitated or deposited. Since the substrate (601) is heated on the hot plate (702), a small amount of the dispersion medium which may fall on the substrate (601) can be vaporized in a short time.

More specifically, the dispersion liquid after the filtering was moved in the solution tank for the airbrush. Using the airbrush (701), the dispersion liquid was sprayed toward the glass substrate (Corning Inc., #1736, non-alkali glass) (601). At the time of spraying, the glass substrate (601) was put on the hot plate (702) to increase the substrate temperature to 150° C. or more. As shown in FIG. 19, the spraying direction of the airbrush (701) was adjusted such that the whole surface of the substrate is not hit by the liquid containing the dispersion medium but coated by the sprayed liquid in the form of mist. However, different from Example 1, one period of spraying is set to about 0.5 seconds (one push of a nozzle of the airbrush (701)). After the liquid in the form of mist disappeared and the glass substrate (601) dried, spraying was carried out again. This step was repeated a hundred times.

As in Example 1, the luminance was measured in the front direction and in the 45° direction. The result of measurement is shown in Table 1. As in Example 1, the structure refractive index and the structure film material refractive index were measured. The result of measurement is shown in Table 2.

### Example 3

A block copolymer was composed of polystyrene (molecular mass is 65000) and polymethacrylate (molecular mass is 13200) by living anion polymerization. The block copolymer having a molecular mass distribution value (weight-average molecular weight (Mw)/number-average molecular weight (Mn)) of 1.04 was used to prepare a solution containing 5% by weight propylene glycol monomethylether acetate. The solution was applied on the glass substrate (601) by spin coating (for 5 seconds at a starting rotation of 500 rmp and for 20 seconds at a main rotation of 2000 rpm).

In an oven which can perform nitrogen substitution, an inside of a layer formed by spin coating was subjected to nitrogen substitution, and then the glass substrate (601) was stored for 4 hours at a temperature of 210° C. and subsequently for 40 hours at a temperature of 135° C. (self-organization by thermal annealing). The thermally treated glass substrate was left standing to cool to ambient temperature. Then, using a RIE (Reactive Ion Etching) apparatus using a CF4 gas, etching is performed for 20 seconds at a gas pressure of 0.1 Torr, a gas feed rate of 30 sccm, and an output of 100 W to form the refractive index composite structure layer (603).

After etching by RIE, over a surface of the substrate (601) facing the refractive index composite structure layer (603), 50 nm of gold was deposited by vacuum deposition to form the optically transparent protection film (605).

Application of toluene solution containing a light emitting material (fluorescent material 1) for organic EL was performed by a spin coater in the ambient atmosphere (for 5 seconds at a starting rotation of 500 rmp, for 15 seconds at a main rotation of 1500 rpm). The glass substrate (601) was heated for about 30 minutes on a hot plate having a temperature of 100° C. to form the light emitting layer (602).

As Example 1, the luminance was measured in the front direction and in the 45° direction. The result of measurement is shown in Table 1. As in Example 1, the structure refractive index and structure film material refractive index were measured. The result of measurement is shown in Table 2. The structure film material refractive index was measured according to the procedure as follows. Several drops of the solution containing 5% by weight propylene glycol monomethylether acetate produced in the present example were directly dropped on the glass substrate which was heated to a temperature of 50° C., and then heated for removing the solvent to form a film. The refractive index of the formed film was measured by the same method as that used for the structure film.

### Example 4

A nano-bubble generation head, which is a porous glass connected to a Synflex® tube (SPG structure available in the market as an SP Finger spray) was inserted in a two-necked flask. Then, photo-curing type resin (radical polymerization type acrylic resin containing fluorine-substituted monomer) was poured into the flask until the porous glass head is soaked in the resin. While stirring with a mechanical stirrer, a nitrogen gas (3 Kgf/cm2) was introduced via the nano-bubble generation head for 30 minutes. Then, the photo-curing type resin which became clouded was sucked into a syringe, and applied on the glass substrate (601) by spin coating (for 5 seconds at a starting rotation of 250 rmp and for 20 seconds at a main rotation of 800 rpm). After the spin coating, UV irradiation was performed for 5 seconds by a high-pressure mercury-vapor lamp (SPOTCURE SP-III, Ushio Inc.) for curing the resin film to form the refractive index composite structure layer (603). An Ar laser beam penetrated through the refractive index composite structure layer (603) on the glass substrate (601) in the direction of normal to the substrate (601) surface. A laser spot at a position distanced by 3 m was measured. It was detected that the beam expanded by 30 cm from the center of the beam.

On the surface of the substrate (601) facing the refractive index composite structure layer (603), 50 nm of gold was deposited by vacuum deposition to form the optically transparent protection film (605). Application of toluene solution containing a light emitting material (fluorescent material 1) for organic EL was performed by a spin coater in the ambient atmosphere (for 5 seconds at a starting rotation of 500 rmp, for 15 seconds at a main rotation of 1500 rpm). The glass substrate (601) was heated for about 30 minutes on a hot plate having a temperature of 100° C. to form the light emitting layer (602).

As in Example 1, the luminance was measured in the front direction and in the 45° direction. The result of measurement is shown in Table 1. As in Example 1, the structure refractive index and structure film material refractive index were measured. The result of measurement is shown in Table 2. The structure film material refractive index was measured according to the procedure as follows. Several drops of the photo-curing type resin (radical polymerization type acrylic resin containing fluorine-substituted monomer) produced in the present example were directly dropped on the glass substrate. Another slide glass substrate was put on the drops on the glass substrate. In this state, the UV irradiation was performed for 5 seconds by the high-pressure mercury-vapor lamp (SPOTCURE SP-III, Ushio Inc.) for curing the resin film. Then, said another slide glass substrate was detached, and the refractive index of the remaining film firmly attached on the glass substrate was measured through the same procedure as that or the structure film.

### Example 5

On the glass substrate (Corning Inc., #1736, non-alkali glass) (601), a toluene solution containing a light emitting material (fluorescent material 1) for organic EL was applied in an ambient atmosphere by a spin coater (for 5 seconds at a starting rotation of 500 rmp, for 15 seconds at a main rotation of 1500 rpm). The glass substrate (601) was heated for about 30 minutes on a hot plate having a temperature of 200° C. to form the light emitting layer (602).

In 20 ml of IPA, 2 g of a micro particle material containing 53 nm particles (the same material as that in Example 1) was diffused. Then, particles greater than or equal to 200 nm were removed by a 0.2 μm millipore filter for removing water type particles.

After the removal, the dispersion liquid was moved in a solution tank for an airbrush. Then, using the airbrush, the dispersion liquid was sprayed toward a surface of the glass substrate (Corning Inc., #1736, non-alkali glass) (601) not facing the light emitting layer (602). Spraying was performed under such a condition that the IPA, which is a particle dispersion agent, vaporizes while the dispersion liquid in the form of mist falls toward the glass substrate (601). To realize the condition, the glass substrate (601) was put on a hot plate with four corners of the glass substrate (601) being supported by 0.1 mm aluminum plates to prevent the light emitting layer (602) from directly touching the hot plate, and the substrate temperature was increased to 150° C. or higher. The spraying of the dispersion liquid was carried out for about 50 seconds, while a sufficient distance was kept for splaying, so that the glass substrate (601) may not hit by the spray drop from the airbrush still containing the IPA. As a result, a structure film, which is a refractive index composite structure layer (603) was formed on the glass substrate (601).

As in Example 1, the luminance was measured in the front direction and the 45° direction. The result of measurement is shown in Table 1.

### Example 6

An organic EL element was produced through the same steps as those of Example 5 excepting the step of forming the structure film by spraying the micro particle material. The step of forming the structure film by spraying the micro particle material in the present example is as follows. The dispersion liquid after the removal was moved in the solution tank for the airbrush. Using the airbrush (701), the dispersion liquid was sprayed toward the glass substrate (Corning Inc., #1736, non-alkali glass) (601). For spraying, the glass substrate (601) was put on the hot plate and the substrate temperature was increased to 150° C. or higher. As shown in FIG. 19, the spraying direction of the airbrush (701) was adjusted such that the whole surface of the substrate is not hit by the liquid containing the dispersion medium but coated by the sprayed liquid in the form of mist. However, it is different from Example 5 in that a period of one spraying is set to about 0.5 seconds (one click of a nozzle of the airbrush (701)). After the liquid in the form of the mist disappeared and the glass substrate (601) dried, spraying was carried out again. This step was repeated a hundred times.

As in Example 1, the luminance was measured in the front direction and in the 45° direction. The result of measurement is shown in Table 1.

### Example 7

As in Example 3, the refractive index composite structure layer (603) was formed on the glass substrate (601). After etching by RIE, a double face adhesive tape having a thickness of about 100 μm was affixed to four corners of a surface of the substrate (601) facing the refractive index composite structure layer (603). Using the double face adhesive tape on the four corners, another glass substrate (hereinafter referred to as protection substrate) was firmly affixed, the size of said another glass substrate being the same as that of the glass substrate (601).

On a surface of the glass substrate (601) not facing the refractive index composite structure layer (603), a toluene solution containing a light emitting material (fluorescent material 1) for organic EL was applied in an ambient atmosphere by a spin coater (for 5 seconds at a starting rotation of 500 rmp and for 15 seconds at a main rotation of 1500 rpm). The glass plate (601) was heated for about 60 minutes on a hot plate having a temperature of 100° C. to form the light emitting layer (602).

The protection substrate was detached, and then as in Example 1, the light emitting layer (602) on the glass substrate (601) was irradiated with 325 nm UV light from the UV lamp (Hamamatsu Photonics K.K., Photocure200). The luminance of fluorescence generated by UV light excitation was measured from a surface of the glass substrate (601) facing the refractive index composite structure layer (603). The result of measurement of the luminance in the front direction and the 45° direction is shown in Table 1.

### Example 8

As in Example 4, the refractive index composite structure layer (603) was formed on the glass substrate (601). As in Example 7, the protection substrate was affixed. Then, the light emitting layer (602) was formed on a surface of the glass substrate (601) not facing the refractive index composite structure layer (603).

The protection substrate was detached, and then the luminance was measured in the front direction and in the 45° direction as in Example 1. The result of measurement is shown in Table 1.

### Comparative Example 1

On a surface of the glass substrate (Corning Inc., #1736, non-alkali glass) (601), 50 nm of gold was deposited by vacuum deposition to form the optically transparent protection film (605). A toluene solution containing a light emitting material (fluorescent material 1) for organic EL was applied in an ambient atmosphere by a spin coater (for 5 seconds at a starting rotation of 500 rmp, for 15 seconds at a main rotation of 1500 rpm). The glass substrate (601) was heated for about 30 minutes on a hot plate having a temperature of 200° C. to form the light emitting layer (602). As in example 1, the luminance was measured in the front direction and 45° direction. The result of measurement is shown in Table 1.

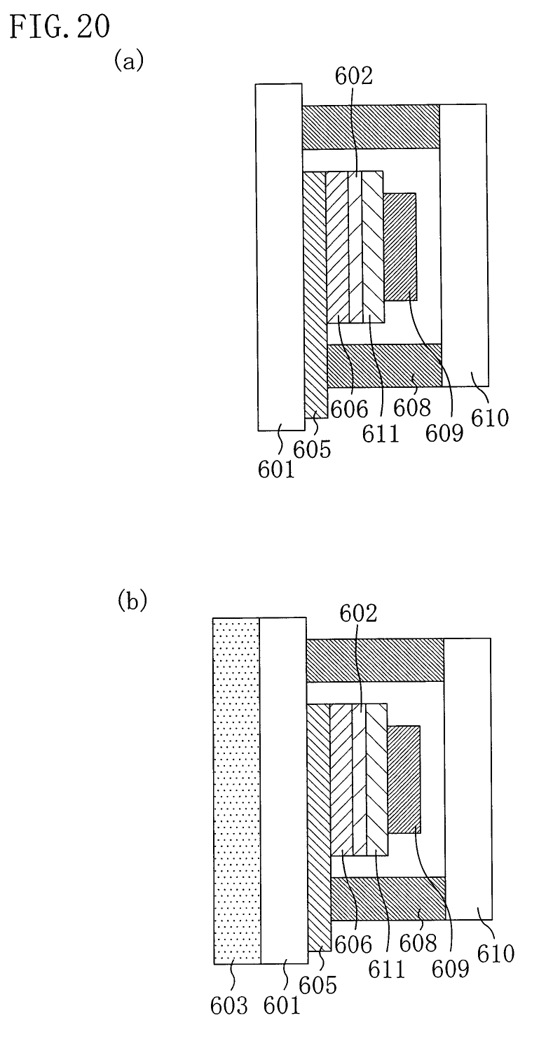

Next, with reference to FIG. 20, an example and a comparative example of a bottom emission type organic EL element are explained. FIG. 20A shows the organic EL element of comparative example 2. FIG. 20B shows the organic EL element of Example 9.

### Comparative Example 2

On a glass substrate (Asahi Glass Co., Ltd., AN-100) (601) with ITO in which an electrode pattern (605) for standard valuation is formed, a 9-fold water dilution solution of a hole transport material was applied by spin coating (for 5 seconds at a starting rotation of 500 rmp, for 15 seconds at a main rotation of 1200 rpm). Then, the glass substrate (601) was heated for about 15 minutes on a hot plate having a temperature of 200° C. to form a hole transport layer (606).

The substrate (601) was left standing to cool, and then moved in a glove box whose dew point is −40° C. In the glove box, spin coating of the fluorescent material 1 (10 mg/10 ml toluene solution) was performed (for 5 seconds at a starting rotation of 500 rmp, for 15 seconds at a main rotation of 1200 rpm). The glass substrate (601) was heated for about 15 minutes on a hot plate having a temperature of 200° C. to form the light emitting layer (602).

After heating, the glass substrate (601) was put in an airtight container, and then pulled out of the glove box. Then, the airtight container was moved in an appurtenant glove box to a vapor deposition apparatus. Then, in the appurtenant glove box, the glass substrate (601) was pulled out of the airtight container and moved in a tray for forming a film in the vapor deposition apparatus. In the vapor deposition apparatus, by vacuum film formation, a Ca film having a thickness of about 50 nm, which is an electron transport layer (611) was deposited. Subsequently, 500 nm Al film, which is a cathode (609) was formed. As a result, an element substrate was formed, wherein a unit area of one organic EL element section is a square of 2 mm.

After the film for the cathode was formed, the substrate (601) was put back in the airtight container in the appurtenant glove box to the vapor deposition apparatus. Then, the airtight container was moved back in the glove box whose dew point is −40° C. Then, the substrate (601) was pulled out of the airtight container. In order to prevent the light emitting element section from being exposed to the air containing water, the light emitting element section of the substrate (601) which was pulled out of the airtight container was encapsulated by seal materials (608) and a seal substrate (610). The seal substrate (610) has a size covering the light emitting element section, and is a cup-shaped glass engraved by sandblast excepting areas where seals are affixed. Moreover, the seal materials (608) are photo-curing type resin for sticking purposes. After the seal is affixed, the seal material (608) was exposed to 6000 mJ/cm2 UV light for curing.

Using a constant current source, a current was applied to the element. The application of current was performed under such a condition that the current value applied to respective organic EL element section is fixed to 0.1 mA. As in Example 1, the luminance was measured in the front direction and the 45° direction. The result of measurement is shown in Table 1.

### Example 9

An organic EL element was produced according to the same method as that in Comparative Example 2. Then, on a surface of the organic EL element from which emitting light is extracted, the refractive index composite structure layer (603) was formed as in Example 2. In this case, the substrate (601) on a hot plate had a temperature of 80° C. or higher, and a dispersion liquid was splayed in such a configuration as shown in FIG. 19. Specifically, the spraying direction and distance were adjusted such that the liquid drops sprayed from the airbrush do not hit the glass substrate (601), with the liquid drop containing isopropyl alcohol. Moreover, a period of one spraying is set to about one second (one long push of nozzle of the airbrush). Then, after the sprayed mist disappeared, the spraying step was repeated fifty times.

As in Comparative Example 9, using the constant current source, application of current was performed under the condition that the current applied to the respective organic EL element section has a fixed value of 0.1 mA. As in Example 1, the luminance was measured in the front direction and the 45° direction. The result of measurement is shown in Table 1.

The luminance of the organic EL element which has the refractive index composite structure layer (603) was measured, and then the refractive index composite structure layer (603) formed on a glass surface of the element from which the light is extracted was sheared. The glass surface from which the refractive index composite structure (603) was sheared was thoroughly wiped with ethanol. Then, the measurement was performed again on substantially the same position and under the same condition. The result of the measurement is shown in Table 1 as “example 9 after the removal of the structure”.

TABLE 1

| | Luminance in front | | Luminance in 45° | |
|---|---|---|---|---|
| Example 1 | 29 | cd/m\hat{ }2 | 36 | cd/m\hat{ }2 |
| Example 2 | 28 | cd/m\hat{ }2 | 35 | cd/m\hat{ }2 |
| Example 3 | 38 | cd/m\hat{ }2 | 40 | cd/m\hat{ }2 |
| Example 4 | 32 | cd/m\hat{ }2 | 38 | cd/m\hat{ }2 |
| Example 5 | 21 | cd/m\hat{ }2 | 23 | cd/m\hat{ }2 |
| Example 6 | 21 | cd/m\hat{ }2 | 23 | cd/m\hat{ }2 |
| Example 7 | 23 | cd/m\hat{ }2 | 25 | cd/m\hat{ }2 |
| Example 8 | 22 | cd/m\hat{ }2 | 24 | cd/m\hat{ }2 |
| Example 9 | 340 | cd/m\hat{ }2 | 350 | cd/m\hat{ }2 |
| Example 9 after | 102 | cd/m\hat{ }2 | 87 | cd/m\hat{ }2 |
| removal of structure | | | | |
| Comparative Example 1 | 8 | cd/m\hat{ }2 | 8 | cd/m\hat{ }2 |
| Comparative Example 2 | 100 | cd/m\hat{ }2 | 85 | cd/m\hat{ }2 |

TABLE 2

| | Structure | Structure film material |
|---|---|---|
| | refractive index | refractive index |
| Example 1 | 1.31 | 1.48 |
| Example 2 | 1.31 | 1.48 |
| Example 3 | 1.24 | 1.47 |
| Example 4 | 1.14 | 1.42 |

From the result in Table 1, it was verified that the structure of the present invention improves the luminance in the front direction and in the 45° direction. This is supported with the comparison made between the characteristic value of Examples 1 through 9 and the characteristic value of Comparative Examples 1 and 2 and the comparison made between the characteristic value of Example 9 (structure is provided on the glass substrate) and the characteristic value of Example 9 after the removal of structure. In other words, it was verified by exemplification in principle configurations in Examples 1 through 8 and the actual organic EL element of Example 9 that the present invention enables to extract part of light which is produced by light emission inside the element but could not be extracted in a conventional element configuration due to excess of the critical angle on interfaces between layers constituting the element, the layers having various functions.

In examples, descriptions have been given with reference to organic EL element. However, the present invention is applicable to other elements. A higher refractive index phase and a lower refractive index phase are accordingly selected, and materials and process conditions are accordingly set for individual elements to which the present invention is to be applied, the higher refractive index phase and the lower refractive index phase forming a targeted refractive index composite structure. Moreover, by adding the step of forming the refractive index composite structure to existing steps of forming a device in order to form the refractive index composite structure inside the light emitting element or outside the element, the light extraction efficiency can be improved as in the organic EL element shown in Examples.

The present invention is applicable to many self-luminous elements, and in every self luminous element, the effect of improving the light extraction efficiency can be obtained. A self-luminous element is currently used as a light emitter, a light source, or a display element. Specifically, examples are a fluorescent tube, a fluorescent display tube, a CRT, a FED, a PDP or a light emitting diode such as a white or blue LED, an organic EL element, an inorganic EL element, or a back light used for, for example, a liquid crystal display apparatus.

While preferred embodiments of the present invention have been described above, it is to be understood that variations and modifications will be apparent to those skilled in the art without departing the scope and spirit of the present invention. The scope of the present invention, therefore, is to be determined solely by the following claims.

1-22. (canceled)

23. An optical functional film including a structure having characteristics (1) to (4) as follows:
(1) an internal configuration including at least two types of phases differing in refractive index;
(2) at least one of the at least two types of phases includes a structural unit having a size greater than or equal to about 1 nm and smaller than or equal to about ¼ of a wavelength within a visible light wavelength range;
(3) an average refractive index is higher than 1 and lower than a refractive index of a plurality of layers between a light emitter and the optical functional film except a layer including a gas phase; and
(4) the internal configuration in a thickness direction includes a plurality of interfaces between the at least two types of phases in a near-field region into which light as energy can enter from an interface between the optical functional film and another layer adjacent to the optical functional film.

24. The optical functional film of claim 23, wherein the structure is a cellular structure formed of one of the at least two types of phases, and the structural unit has a thickness of a wall constituting the cellular structure and/or a size of a gap between the wall constituting the cellular structure and another wall facing the wall constituting the cellular structure.

25. The optical functional film of claim 23, wherein the structure is a network structure formed of one of the at least two types of phases, and the structural unit has at least one dimension selected from the group consisting of a diameter of fibers constituting the network structure, a distance between the fibers, and a size of a gap formed by the network structure.

26. The optical functional film of claim 23, wherein the structure is a block structure which is formed of one of the at least two types of phases, and the structural unit has a diameter of the block structure or a size of a gap between the block structures.

27. The optical functional film of claim 23, wherein at least one of the at least two types of phases has a characteristic which permits self-retaining the structure at least within a temperature range centering around ambient temperature in which an element operates, and the at least two types of phases include a first phase having a refractive index of lower than or equal to about 1.4 and a second phase having a refractive index of higher than or equal to about 1.3.

28. The optical functional film of claim 27, wherein the first phase is a gas phase.

29. The optical functional film of claim 28, wherein the first phase is in a vacuum state or in a low pressure state in which pressure is lower than atmospheric pressure.

30. The optical functional film of claim 27, wherein at least one of the at least two types of phases is a liquid phase.

31. A light emitting element having a light emitting layer emitting light, comprising:
at least one of the optical functional film of claim 23 arranged in a light path along which light output from the light emitting layer travels before exiting the light emitting element.

32. A film which is to be stuck to, pressed on, or put on a light emitting element having a light emitting layer emitting light, comprising:
at least one of the optical functional film of claim 23 arranged in a light path along which light output from the light emitting layer travels before exiting the light emitting element.

33. A plate member which is to be stuck to, pressed on, or put on a light emitting element having a light emitting layer emitting light, comprising:
at least one optical functional film of claim 23 arranged in a light path along which light output from the light emitting layer travels before exiting the light emitting element.

34. A molded object whose shape is suitable for the shape of a light emitting element having a light emitting layer emitting light, comprising:
at least one of the optical functional film of claim 23 arranged in a light path along which light output from the light emitting layer travels before exiting the light emitting element.

35. The light emitting element of claim 31, wherein the structure is located in a position to which more than or equal to about 15% of light energy on the interface between the optical functional film and said another layer arrives.

36. The film of claim 32, wherein the structure is located in a position to which more than or equal to about 15% of light energy on the interface between the optical functional film and said another layer arrives.

37. The plate member of claim 33, wherein the structure is located in a position to which more than or equal to about 15% of light energy on the interface between the optical functional film and said another layer arrives.

38. The molded object of claim 34, wherein the structure is located in a position to which more than or equal to about 15% of light energy on the interface between the optical functional film and said another layer arrives.

39. A method of forming the optical functional film of claim 23, comprising the steps of:
dispersing micro particles having a size of the structural unit in an application solvent to prepare a micro particle dispersion liquid;
applying the micro particle dispersion liquid in a liquid state over a substrate; and
removing the application solvent followed by bonding micro particles to each other and/or to the substrate to form the structure.

40. A method of forming the optical functional film of claim 23, comprising the steps of:
dispersing micro particles having a size of the structural unit in an application solvent to prepare a micro particle dispersion liquid;
spraying the micro particle dispersion liquid in the form of micro liquid drops and vaporizing the application solvent while the micro liquid drops are in an atmosphere for deposition of the micro particles on a substrate; and
bonding micro particles to each other and/or to the substrate to form the structure.

41. A method of forming the optical functional film of claim 23, comprising the steps of:
forming a composite structure by self-organization or phase separation of at least two components which have no stable phase compatibility and are separate from each other;
removing one of the components of the structure using a difference in etching rate under a specific etching atmosphere or in dissolution rate for a specific solvent according to the composite structure to form the structure.

42. A method of forming the optical functional film of claim 23, comprising the step of:
causing a reaction in a solution for producing a micellar state to form the structure.

43. A method of forming the optical functional film of claim 23, comprising the steps of:
generating bubbles in a resin before curing, the bubbles being greater than or equal to about 1 nm and smaller than or equal to about 0.1 μm; and
curing the resin with the bubbles stably dispersed to form the structure.

44. The method of claim 43, wherein the bubbles are formed by introducing a gas through a porous structure having a pore diameter greater than or equal to about 1 nm and smaller than or equal to about 0.1 μm.
